(19) United States
(12) Patent Application Publication
(10) Pub. No.: US 2023/0411371 A1
(43) Pub. Date: Dec. 21, 2023

(54) DISPLAY DEVICE AND METHOD FOR MANUFACTURING THE SAME

(71) Applicant: Samsung Display Co., LTD., Yongin-si (KR)

(72) Inventors: Jong Chan Lee, Yongin-si (KR); Jin Taek Kim, Yongin-si (KR); Jeong Su Park, Yongin-si (KR); Sung Jin Lee, Yongin-si (KR); Hyun Wook Lee, Yongin-si (KR); Woong Hee Jeong, Yongin-si (KR)

(73) Assignee: Samsung Display Co., LTD., Yongin-si (KR)

(21) Appl. No.: 18/110,101

(22) Filed: Feb. 15, 2023

(30) Foreign Application Priority Data
Jun. 20, 2022 (KR) 10-2022-0074817

(51) Int. Cl. H01L 25/16; H01L 27/12; H01L 33/62

(52) U.S. Cl. CPC H01L 25/167; H01L 33/62; H01L 27/124

(57) ABSTRACT

A display device includes a bank layer disposed on a substrate and defining an emission area, a first to sixth alignment electrodes, each disposed on the substrate extending across the emission area, spaced apart from each other, and sequentially arranged in a direction, a first light emitting element disposed between the first alignment electrode and the second alignment electrode in the emission area and emitting first light, a second light emitting element disposed between the third alignment electrode and the fourth alignment electrode in the emission area and emitting second light, and a third light emitting element disposed between the fifth alignment electrode and the sixth alignment electrode in the emission area and emitting third light. Wavelengths of the first light, the second light, and the third light are different from each other.

### CROSS-REFERENCE TO RELATED APPLICATION(S)

This application claims priority to and benefits of Korean Patent Application No. 10-2022-0074817 under 35 U.S.C. 119, filed on Jun. 20, 2022, in the Korean Intellectual Property Office (KIPO), the entire contents of which are incorporated herein by reference.

### BACKGROUND

### 1. Technical Field

The disclosure relates to a display device and a method for manufacturing the same.

### 2. Description of the Related Art

The importance of display devices has steadily increased with the development of multimedia technology. In response thereto, various types of display devices such as an organic light emitting display (OLED), a liquid crystal display (LCD) and the like have been used.

A display device is a device for displaying an image, and includes a display panel, such as an organic light emitting display panel or a liquid crystal display panel. The light emitting display panel may include light emitting elements, e.g., light emitting diodes (LED), and examples of the light emitting diode include an organic light emitting diode (OLED) using an organic material as a light emitting material and an inorganic light emitting diode using an inorganic material as a light emitting material.

An inorganic light emitting diode using an inorganic semiconductor as a fluorescent material has an advantage in that it has durability even in a high temperature environment, and has higher efficiency of blue light than an organic light emitting diode.

### SUMMARY

Aspects of the disclosure provide a display device implementing high resolution.

Aspects of the disclosure also provide a method of manufacturing a display device implementing high resolution.

According to an embodiment of the disclosure, a display device may include a bank layer disposed on a substrate and defining an emission area, a first alignment electrode, a second alignment electrode, a third alignment electrode, a fourth alignment electrode, a fifth alignment electrode, and a sixth alignment electrode, each disposed on the substrate extending across the emission area, spaced apart from each other, and sequentially arranged in a direction, a first light emitting element disposed between the first alignment electrode and the second alignment electrode in the emission area and emitting first light, a second light emitting element disposed between the third alignment electrode and the fourth alignment electrode in the emission area and emitting second light, and a third light emitting element disposed between the fifth alignment electrode and the sixth alignment electrode in the emission area and emitting third light. Wavelengths of the first light, the second light, and the third light may be different from each other.

In an embodiment, a length of the first light emitting element, a length of the second light emitting element, and a length of the third light emitting element in the direction may be different from each other.

In an embodiment, the first light may have a peak wavelength in a range of about 610 nm to about 650 nm, the second light may have a peak wavelength in a range of about 510 nm to about 550 nm, and the third light may have a peak wavelength in a range of about 440 nm to about 480 nm.

In an embodiment, the length of the first light emitting element may be greater than the length of the second light emitting element, and the length of the second light emitting element may be greater than the length of the third light emitting element.

In an embodiment, the display device may further include an anchor portion disposed on the first light emitting element, the second light emitting element, and the third light emitting element and exposing both ends of each of the first light emitting element, the second light emitting element, and the third light emitting element. The anchor portion may include an organic insulating material.

In an embodiment, a distance between the first alignment electrode and the second alignment electrode may be greater than a distance between the third alignment electrode and the fourth alignment electrode in the direction, and the distance between the third alignment electrode and the fourth alignment electrode may be greater than a distance between the fifth alignment electrode and the sixth alignment electrode in the direction.

In an embodiment, the length of the first light emitting element may be greater than the distance between the first alignment electrode and the second alignment electrode, the length of the second light emitting element may be greater than the distance between the third alignment electrode and the fourth alignment electrode, and the length of the third light emitting element may be greater than the distance between the fifth alignment electrode and the sixth alignment electrode.

In an embodiment, the display device may further include a via insulating layer disposed between the substrate and each of the first alignment electrode, the second alignment electrode, the third alignment electrode, the fourth alignment electrode, the fifth alignment electrode, and the sixth alignment electrode. The each of the first alignment electrode, the second alignment electrode, the third alignment electrode, the fourth alignment electrode, the fifth alignment electrode, and the sixth alignment electrode may have a flat profile in the emission area.

In an embodiment, a bottom surface of the each of the first alignment electrode, the second alignment electrode, the third alignment electrode, the fourth alignment electrode, the fifth alignment electrode, and the sixth alignment electrode may completely contact a top surface of the via insulating layer in the emission area.

According to an embodiment of the disclosure a display device may include a bank layer disposed on a substrate and defining an emission area, a first alignment electrode, a second alignment electrode, a third alignment electrode, and a fourth alignment electrode, each disposed on the substrate extending across the emission area, spaced apart from each other, and sequentially arranged in a direction, a first light emitting element disposed between the first alignment electrode and the second alignment electrode in the emission area and emitting first light, a second light emitting element disposed between the second alignment electrode and the third alignment electrode in the emission area and emitting second light, and a third light emitting element disposed between the third alignment electrode and the fourth alignment electrode in the emission area and emitting third light. Wavelengths of the first light, the second light, and the third light may be different from each other.

In an embodiment, a length of the first light emitting element, a length of the second light emitting element, and a length of the third light emitting element in the direction may be different from each other.

In an embodiment, the first light may have a peak wavelength in a range of about 610 nm to about 650 nm, the second light may have a peak wavelength in a range of about 510 nm to about 550 nm, and the third light may have a peak wavelength in a range of about 440 nm to about 480 nm.

In an embodiment, the length of the first light emitting element may be greater than the length of the second light emitting element, and the length of the second light emitting element may be greater than the length of the third light emitting element.

In an embodiment, a distance between the first alignment electrode and the second alignment electrode may be greater than a distance between the second alignment electrode and the third alignment electrode in the direction, and the distance between the second alignment electrode and the third alignment electrode may be greater than a distance between the third alignment electrode and the fourth alignment electrode in the direction.

In an embodiment, each of the first light emitting element, the second light emitting element, and the third light emitting element may have a first end and a second end having different polarities, the second end of the first light emitting element may face the first end of the second light emitting element, and the second end of the second light emitting element may face the first end of the third light emitting element.

In an embodiment, the display device may further include a first connection electrode disposed on the first alignment electrode, a second connection electrode disposed on the second alignment electrode, a third connection electrode disposed on the third alignment electrode, and a fourth connection electrode disposed on the fourth alignment electrode. The first connection electrode may electrically contact the first end of the first light emitting element, the second connection electrode may electrically contact the second end of the first light emitting element and the first end of the second light emitting element, the third connection electrode may electrically contact the second end of the second light emitting element and the first end of the third light emitting element, and the fourth connection electrode may electrically contact the second end of the third light emitting element.

In an embodiment, each of the first connection electrode, the second connection electrode, the third connection electrode, and the fourth connection electrode may receive a first voltage and a second voltage having different potential values.

In an embodiment, the display device may further include an anchor portion disposed on the first light emitting element, the second light emitting element, and the third light emitting element and exposing the first end and the second end of each of the first light emitting element, the second light emitting element, and the third light emitting element. The anchor portion may include an organic insulating material.

In an embodiment, the display device may further include a via insulating layer disposed between the substrate and each of the first alignment electrode, the second alignment electrode, the third alignment electrode, and the fourth alignment electrode. The each of the first alignment electrode, the second alignment electrode, the third alignment electrode, and the fourth alignment electrode may have a flat profile in the emission area.

In an embodiment, a bottom surface of the each of the first alignment electrode, the second alignment electrode, the third alignment electrode, and the fourth alignment electrode may completely contact a top surface of the via insulating layer in the emission area.

However, aspects of the disclosure are not restricted to those set forth herein. The above and other aspects of the disclosure will become more apparent to one of ordinary skill in the art to which the disclosure pertains by referencing the detailed description of the disclosure given below.

In the display device according to one embodiment, high-resolution may be implemented.

In the method for manufacturing a display device according to one embodiment, a display device implementing high-resolution may be provided.

It should be noted that the effects of the disclosure are not limited to those described above, and other effects of the disclosure will be apparent from the following description.

### BRIEF DESCRIPTION OF THE DRAWINGS

The above and other aspects and features of the disclosure will become more apparent by describing in detail embodiments thereof with reference to the attached drawings, in which:

FIG. 1 is a plan view illustrating a display device according to one embodiment;

FIG. 2 is a schematic diagram of an equivalent circuit of an emission portion disposed on a pixel of a display device according to one embodiment;

FIG. 3 is a plan view illustrating an arrangement of multiple pixels of a display device according to one embodiment;

FIG. 4 is a perspective view illustrating a light emitting element of a display device according to one embodiment;

FIG. 5 is an enlarged view of area A of FIG. 3;

FIG. 6 is a schematic cross-sectional view of a pixel taken along line X1-X1′ of FIG. 5;

FIG. 7 is a schematic cross-sectional view of a pixel taken along line X2-X2′ of FIG. 5;

FIGS. 8 through 23 are views for explaining a process for manufacturing a display device according to one embodiment;

FIG. 24 is a plan view illustrating a pixel structure of a display device according to another embodiment;

FIG. 25 is a schematic cross-sectional view of a pixel taken along line X3-X3′ of FIG. 24; and

FIGS. 26 through 33 are views for explaining a process for driving light emitting elements of a display device according to embodiment of FIG. 24.

### DETAILED DESCRIPTION OF THE EMBODIMENTS

The embodiments will now be described more fully hereinafter with reference to the accompanying drawings, in which embodiments of the disclosure are shown. The disclosure may, however, be embodied in different forms and should not be construed as limited to the embodiments set forth herein. Rather, these embodiments are provided so that this disclosure will be more thorough and complete, and will fully convey the scope of the disclosure to those skilled in the art.

When an element, such as a layer, is referred to as being “on”, “connected to”, or “coupled to” another element or layer, it may be directly on, connected to, or coupled to the other element or layer or intervening elements or layers may be present. When, however, an element or layer is referred to as being “directly on”, “directly connected to”, or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

In the specification and the claims, the phrase “at least one of” is intended to include the meaning of “at least one selected from the group of” for the purpose of its meaning and interpretation. For example, “at least one of A and B” may be understood to mean “A, B, or A and B.”

Features of each of various embodiments of the disclosure may be partially or entirely combined with each other and may technically variously interwork with each other, and respective embodiments may be implemented independently of each other or may be implemented together in association with each other.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, specific embodiments will be described with reference to the accompanying drawings.

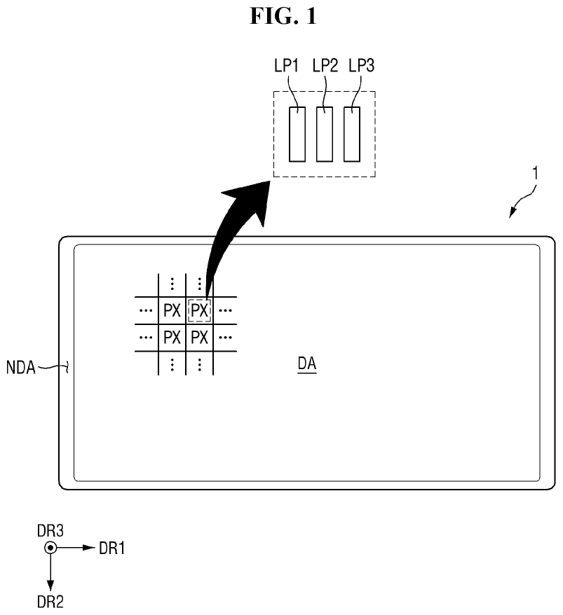

FIG. 1 is a plan view illustrating a display device according to one embodiment.

In FIG. 1, a first direction DR1, a second direction DR2, and a third direction DR3 are defined. The first direction DR1 and the second direction DR2 may be perpendicular to each other, the first direction DR1 and the third direction DR3 may be perpendicular to each other, and the second direction DR2 and the third direction DR3 may be perpendicular to each other. It may be understood that the first direction DR1 refers to a horizontal direction in the drawing, the second direction DR2 refers to a vertical direction in the drawing, and the third direction DR3 refers to an up-down direction in the drawing, for example, a thickness direction.

In the following specification, unless otherwise specified, a “direction” may refer to both directions extending to both sides along the direction. In addition, when it is necessary to distinguish both “directions” extending to both sides, one side is referred to as “one side in the direction,” and the other side is referred to as “the other side in the direction.” Based on FIG. 1, a direction in which an arrow is directed is referred to as one side, and a direction opposite to the direction is referred to as the other side.

Hereinafter, for ease of description, in referring to surfaces of the display device 1 or each member constituting the display device 1, one surface facing one side in the direction in which an image is displayed, for example, the third direction DR3, is referred to as a top surface, and a surface opposite the one surface is referred to as a bottom surface. However, the disclosure is not limited thereto, and the one surface and the other surface of each member may also be referred to as a front surface and a rear surface, respectively, or may be referred to as a first surface and a second surface. In addition, in describing relative positions of the members of a display device 1, a side in the third direction DR3 may be referred to as an upper side, and another side in the third direction DR3 may be referred to as a lower side.

Referring to FIG. 1, a display device 1 may display a moving image or a still image. The display device 1 may be any electronic device providing a display screen. Examples of the display device 1 may include a television, a laptop computer, a monitor, a billboard, an Internet-of-Things device, a mobile phone, a smartphone, a tablet personal computer (PC), an electronic watch, a smart watch, a watch phone, a head-mounted display, a mobile communication terminal, an electronic notebook, an electronic book, a portable multimedia player (PMP), a navigation device, a game machine, a digital camera, a camcorder and the like, which provide a display screen.

The display device 1 may include a display panel which provides a display screen. Examples of the display panel may include an inorganic light emitting diode display panel, an organic light emitting display panel, a quantum dot light emitting display panel, a plasma display panel, and a field emission display panel. In the following description, a case where an inorganic light emitting diode display panel is applied as a display panel will be described, but the disclosure is not limited thereto, and other display panels may be applied within the same scope of technical spirit.

The shape of the display device 1 may be variously modified. For example, the display device 1 may have a shape such as a rectangular shape elongated in a horizontal direction, a rectangular shape elongated in a vertical direction, a square shape, a quadrilateral shape with rounded corners (vertices), a polygonal shape, and a circular shape. The shape of a display area DA of the display device 1 may also be similar to the overall shape of the display device 10. FIG. 1 illustrates the display device 1 having a rectangular shape elongated in a first direction DR1.

The display device 1 may include the display area DA and a non-display area NDA. The display area DA may be an area where a screen can be displayed, and the non-display area NDA may be an area where a screen is not displayed. The display area DA may also be referred to as an active region, and the non-display area NDA may also be referred to as a non-active region. The display area DA may substantially occupy the center of the display device 10, but the disclosure is not limited thereto.

The display area DPA may include multiple pixels PX. The pixels PX may be arranged in matrix. The shape of each pixel PX may be a rectangular or square shape in a plan view. However, the disclosure is not limited thereto, and it may be a rhombic shape in which each side is inclined with respect to a direction. The pixels PX may be arranged in a stripe type or an island type. Each of the pixels PX may include one or more light emitting elements that emit light of a specific wavelength band to display a specific color.

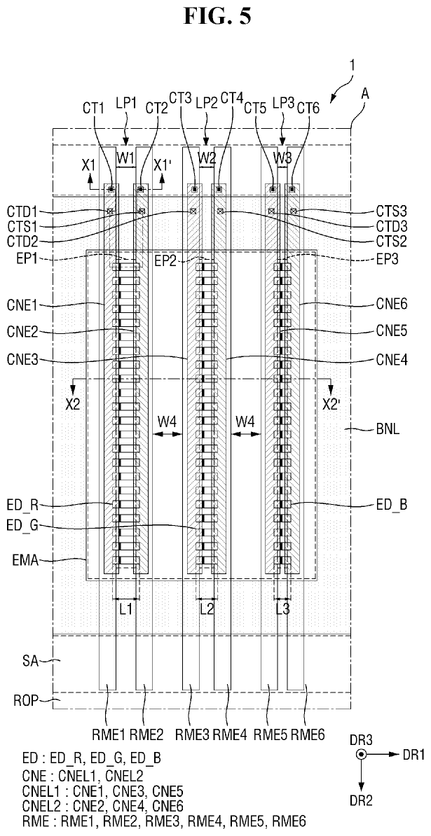

Each of the pixels may include multiple emission portions LP1, LP2, and LP3. Each of the pixels PX may include a first emission portion LP1, a second emission portion LP2, and a third emission portion LP3. The first emission portion LP1, the second emission portion LP2, and the third emission portion LP3 may be disposed in the emission area EMA (see FIG. 5) defined in each of the pixels PX.

The first emission portion LP1 may emit light of a first color, the second emission portion LP2 may emit light of a second color, and the third emission portion LP3 may emit light of a third color. For example, the light of the first color may be red light having a peak wavelength in the range of about 610 to about 650 nm, the light of the second color may be green light having a peak wavelength in the range of about 510 to about 550 nm, and the light of the third color may be blue light having a peak wavelength in the range of about 440 to about 480 nm. Each of the emission portions may include light emitting elements different from each other emitting light of different peak wavelength. This will be described in more detail later. It is, however, to be understood that the disclosure is not limited thereto. Each of the emission portions may include light emitting elements emitting light of a same peak wavelength.

The non-display area NDA may be disposed adjacent to the display area DA. For example, the non-display area NDA may be disposed to surround the display area DA. In some embodiments, the non-display area NDA may be disposed to be adjacent to four sides of the display area DA, but the disclosure is not limited thereto. The non-display areas NDA may form the bezel of the display device 1. Wirings or circuit drivers included in the display device 1 may be disposed in the non-display area NDA, or external devices may be mounted thereon.

Hereinafter, a circuit structure of emission portions LP1, LP2 and LP3 of a pixel PX disposed in the display device 1 according to one embodiment will be described.

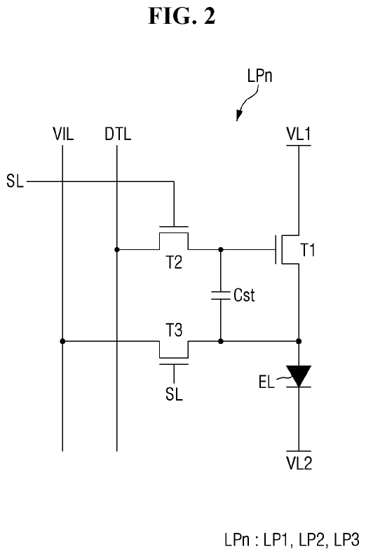

FIG. 2 is a schematic diagram of an equivalent circuit of an emission portion disposed on a pixel of a display device according to one embodiment.

Referring to FIG. 2, emission portion LPn (n is an integer of 1 to 3) of each pixel PX of the display device 1 may include a driving circuit. The driving circuit may include transistors and capacitors. The number of transistors and capacitors of each pixel driving circuit may be variously modified. According to one embodiment, in each emission portion LPn of the pixel PX, the driving circuit may have a 3T1C structure including three transistors and one capacitor. Hereinafter, the pixel driving circuit of the 3T1C structure will be described according to an embodiment, but the disclosure is not limited thereto, and various other modified pixel PX structures such as a 2T1C structure, a 7T1C structure, and a 6T1C structure may be applied.

Each emission portion LPn of the display device 1 according to one embodiment may include three transistors T1, T2 and T3 and one storage capacitor Cst in addition to a light emitting diode EL.

The light emitting diode EL may emit light by a current supplied through a first transistor T1. The light emitting diode EL may include a first electrode, a second electrode, and at least one light emitting element disposed between them. The light emitting element may emit light of a specific wavelength band by electrical signals transmitted from the first electrode and the second electrode.

An end of the light emitting diode EL may be connected to the source electrode of the first transistor T1, and another end thereof may be connected to the second voltage wire VL2 to which a low potential voltage (hereinafter, a second power voltage) lower than a high potential voltage (hereinafter, a first power voltage) of the first voltage wire VL1 is supplied.

The first transistor T1 may adjust a current flowing from the first voltage wire VL1, to which the first power voltage is supplied, to the light emitting diode EL according to the voltage difference between the gate electrode and the source electrode. For example, the first transistor T1 may be a driving transistor for driving the light emitting diode EL. The gate electrode of the first transistor T1 may be connected to the source electrode of a second transistor T2, the source electrode of the first transistor T1 may be connected to the first electrode of the light emitting diode EL, and the drain electrode of the first transistor T1 may be connected to the first voltage wire VL1 to which the first power voltage is applied.

The second transistor T2 may be turned on by a scan signal of the scan line SL to connect a data line DTL to the gate electrode of the first transistor T1. The gate electrode of the second transistor T2 may be connected to the scan line SL, the source electrode thereof may be connected to the gate electrode of the first transistor T1, and the drain electrode thereof may be connected to the data line DTL.

The third transistor T3 may be turned on by a scan signal of the scan line SL to connect the initialization voltage wire VIL to the first electrode of the light emitting diode EL. The gate electrode of the third transistor T3 may be connected to the scan line SL, the drain electrode thereof may be connected to the initialization voltage wire VIL, and the source electrode thereof may be connected to the first electrode of the light emitting diode EL or to the source electrode of the first transistor T1.

However, the source electrode and the drain electrode of each of the transistors T1, T2, and T3 are not limited to those described above. Each of the transistors T1, T2, and T3 may be formed of a thin film transistor. In FIG. 2, each of the transistors T1, T2, and T3 are described as being formed of an N-type metal oxide semiconductor field effect transistor (MOSFET), but the disclosure is not limited thereto. For example, each of the transistors T1, T2, and T3 may be formed of a P-type MOSFET. In another embodiment, some of the transistors T1, T2, and T3 may be formed of an N-type MOSFET and the others may be formed of a P-type MOSFET.

The storage capacitor Cst may be formed between the gate electrode and the source electrode of the first transistor T1. The storage capacitor Cst may store a difference in voltage between a gate electrode and a source electrode of the first transistor T1.

In one embodiment, the gate electrode of the second transistor T2 may be connected to the scan line SL and the gate electrode of the third transistor T3 may be connected to the scan line SL. In other words, the second transistor T2 and the third transistor T3 may be turned on by a scan signal applied from the same scan line. However, the disclosure is not limited thereto, and the second transistor T2 and the third transistor T3 may be connected to different scan lines and be turned on by scan signals applied from different scan lines.

Hereinafter, a pixel PX structure of the display device 1 according to one embodiment will be described.

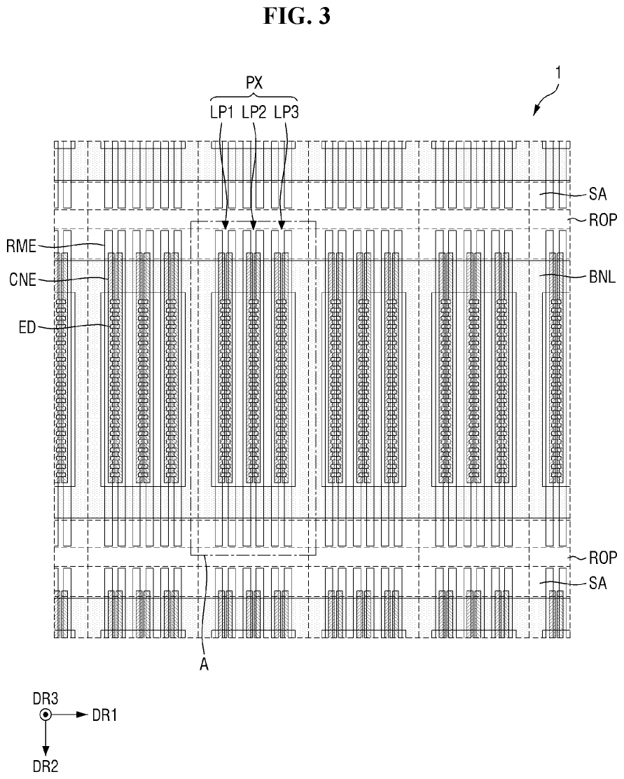

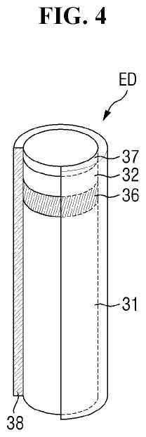

FIG. 3 is a plan view illustrating an arrangement of multiple pixels of a display device according to one embodiment. FIG. 4 is a perspective view illustrating a light emitting element of a display device according to one embodiment. FIG. 5 is an enlarged view of area A of FIG. 3.

Referring to FIGS. 3 to 5, each of the pixels PX according to one embodiment may be arranged along the first direction DR1. Each of the pixels PX may include emission area EMA and the first emission portion LP1, the second emission portion LP2, and the third emission portion LP3 may be disposed in the emission area EMA of each of the pixels PX.

Each pixel PX of the display device 1 may include an emission area EMA and a non-emission area. The emission area EMA may be an area in which the light emitting elements ED are disposed to emit light of a specific wavelength band. The non-emission area may be an area in which the light emitting elements ED are not disposed and from which no light is output because light emitted from the light emitting elements ED does not reach this area.

The emission area EMA may be defined by a bank layer BNL. In other words, the emission area EMA may be a space surrounded by the bank layer BNL. In some embodiments, the emission area EMA may have a rectangular shape having short sides in the first direction DR1 and long sides in the second direction DR2, but the disclosure is not limited thereto.

The emission area EMA may include a region in which the light emitting element ED is disposed, and a region adjacent to the light emitting element ED and from which lights emitted from the light emitting element ED are emitted. For example, the emission area EMA may further include a region in which the light emitted from the light emitting element ED is reflected or refracted by another member and emitted. The light emitting elements ED may be disposed in each emission portion LPn, and the emission area may be formed to include an area where the light emitting elements ED are disposed and an area adjacent thereto.

Each pixel PX may further include a sub-area SA disposed in the non-emission area. The sub-area SA may be a divided area according to the arrangement of the alignment electrodes RME. The sub-area SA may be disposed on a side and another side of the emission area EMA in the second direction DR2. The light emitting areas EMA may be alternately arranged in the first direction DR1, and the sub areas SA may extend in the first direction DR1. Each of the light emitting areas and sub-areas SA may be repeatedly disposed in the second direction DR2. Each of the light emitting areas EMA may be disposed between the sub-areas SA.

The sub-area SA may be an area shared by the pixels PX adjacent in the first direction DR1. The sub-area SA may be an area shared by the pixels PX adjacent in the second direction DR2.

Light may not be emitted from the sub-area SA because the light emitting element ED is not disposed in the sub-area SA, but alignment electrodes RME disposed in each pixel PX may be partially disposed in the sub-area SA. The alignment electrodes RME disposed in different pixels PX may be disposed to be separated from each other in the separation portion ROP of the sub-area SA.

The alignment electrodes RME may extend to cross the emission area EMA in the second direction DR2. In some embodiments, the alignment electrodes RME may pass the bank layer BNL which defines the emission area EMA and extend to the sub-area SA disposed on both sides of the bank layer BNL in the second direction DR2, but the disclosure is not limited thereto.

Six alignment electrodes RME may be disposed in the emission area EMA of each pixel, but the disclosure is not limited thereto. In FIG. 3, six alignment electrodes RME are disposed in the emission area EMA of each pixel PX.

The alignment electrode RME may include a first alignment electrode RME1, a second alignment electrode RME2, a third alignment electrode RME3, a fourth alignment electrode RME4, a fifth alignment electrode RME5, and a sixth alignment electrode RME6 sequentially arranged in the first direction DR1. For example, the second alignment electrode RME2 may be disposed on a side of the first alignment electrode RME1 in the first direction DR1, the third alignment electrode RME3 may be disposed on a side of the second alignment electrode RME2 in the first direction DR1, the fourth alignment electrode RME4 may be disposed on a side of the third alignment electrode RME3 in the first direction DR1, the fifth alignment electrode RME5 may be disposed on a side of the fourth alignment electrode RME4 in the first direction DR1, and the sixth alignment electrode RME6 may be disposed on a side of the fifth alignment electrode RME5 in the first direction DR1.

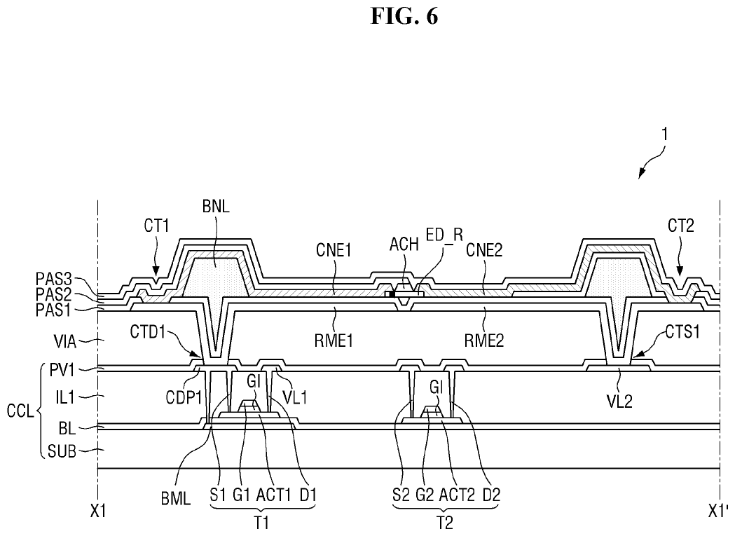

Each of the alignment electrodes RME may be electrically connected to the circuit element layer CCL (see FIG. 6) to be described later through electrode contact holes. For example, the first alignment electrode RME1 may be electrically connected to the circuit element layer CCL through a first electrode contact hole CTD1, the second alignment electrode RME2 may be electrically connected to the circuit element layer CCL through a second electrode contact hole CTS1, the third alignment electrode RME3 may be electrically connected to the circuit element layer CCL through a third electrode contact hole CTD2, the fourth alignment electrode RME4 may be electrically connected to the circuit element layer CCL through a fourth electrode contact hole CTS2, the fifth alignment electrode RME5 may be electrically connected to the circuit element layer CCL through a fifth electrode contact hole CTD3, and the sixth alignment electrode RME6 may be electrically connected to the circuit element layer CCL through a sixth electrode contact hole CTS3. Accordingly, the first alignment electrode RME1, the third alignment electrode RME3, and the fifth alignment electrode RME5 may receive a first power voltage described above, and the second alignment electrode RME2, the fourth alignment electrode RME4, and the sixth alignment electrode RME6 may receive a second power voltage described above.

The first alignment electrode RME1, the second alignment electrode RME2, the third alignment electrode RME3, the fourth alignment electrode RME4, the fifth alignment electrode RME5, and the sixth alignment electrode RME6 may each be spaced apart in the first direction DR1.

For example, the first alignment electrode RME1 and the second alignment electrode RME2 may be spaced apart by a first width W1 to form a first yarn path EP1, the third alignment electrode RME3 and the fourth alignment electrode RME4 may be spaced apart by a second width W2 to form a second yarn path EP2, and the fifth alignment electrode RME5 and the sixth alignment electrode RME6 may be spaced apart by a third width W3 to form a third yarn path EP3. Accordingly, the width of the first yarn path EP1 in the first direction DR1 may be substantially the same as the first width W1, the width of the second yarn path EP2 in the first direction DR1 may be substantially the same as the second width W2, and the width of the third yarn path EP3 in the first direction DR1 may be substantially the same as the third width W3. In some embodiments, the first width W1 may be greater than the second width W2 and the second width W2 may be greater than the third width W3, but the disclosure is not limited thereto. In FIG. 5, a configuration in which the first width W1 is greater than the second width W2 and the second width W2 is greater than the third width W3 is illustrated.

The light emitting elements ED may be arranged in the second direction DR2 in the space between the first alignment electrode RME1 and the second alignment electrode RME2, in the space between the third alignment electrode RME3 and the fourth alignment electrode RME4, and in the space between the fifth alignment electrode RME5 and the sixth alignment electrode RME6. In other words, light emitting elements ED may be arranged in each of the first emission portion LP1, the second emission portion LP2, and the third emission portion LP3. This will be described later.

The second alignment electrode RME2 and the third alignment electrode RME3 may be spaced apart in the first direction DR1 by a fourth width W4 and the fourth alignment electrode RME4 and the fifth alignment electrode RME5 may be spaced apart in the first direction DR1 by a fourth width W4. The light emitting element ED may not be disposed in the space between the second alignment electrode RME2 and the third alignment electrode RME3 and the space between the fourth alignment electrode RME4 and the fifth alignment electrode RME5. In some embodiments, the fourth width W4 may be greater than the first width W1, but the disclosure is not limited thereto.

Referring to FIG. 4, the light emitting element ED may be a light emitting diode. For example, the light emitting element ED may be an inorganic light emitting diode that has a nanometer or micrometer size, and is made of an inorganic material. The light emitting element ED may be aligned between two electrodes having polarity in case that an electric field is formed in a specific direction between two electrodes opposing each other.

The light emitting element ED according to an embodiment may have a shape elongated in one direction. The light emitting element ED may have a shape of a cylinder, a rod, a wire, a tube, or the like. However, the shape of the light emitting element ED is not limited thereto, and the light emitting element ED may have a polygonal prism shape such as a regular cube, a rectangular parallelepiped, and a hexagonal prism, or may have various shapes such as a shape elongated in one direction and having an outer surface partially inclined.

The light emitting element ED may include a semiconductor layer doped with a conductivity type (e.g., p-type or n-type) impurity. The semiconductor layer may emit light of a specific wavelength band by receiving an electrical signal applied from an external power source. The light emitting element ED may include a first semiconductor layer 31, a second semiconductor layer 32, a light emitting layer 36, an electrode layer 37, and an insulating layer 38.

The first semiconductor layer 31 may be an n-type semiconductor. The first semiconductor layer 31 may include a semiconductor material having a chemical formula of AlₓGa_{y}In1_{-x-y}N (0≤x≤1, 0≤y≤1, 0≤x+y≤1). For example, it may be any one or more of n-type doped AlGaInN, GaN, AlGaN, InGaN, AlN, and InN. The n-type dopant doped into the first semiconductor layer 31 may be Si, Ge, Sn, Se, or the like.

The second semiconductor layer 32 may be disposed on the first semiconductor layer 31 with the light emitting layer 36 therebetween. The second semiconductor layer 32 may be a p-type semiconductor, and the second semiconductor layer 32 may include a semiconductor material having a chemical formula of AlₓGa_{y}In_{1-x-y}N (0≤x≤1, 0≤y≤1, 0≤x+y≤1). For example, it may be any one or more of p-type dopant doped AlGaInN, GaN, AlGaN, InGaN, AlN, and InN. The p-type dopant doped into the second semiconductor layer 32 may be Mg, Zn, Ca, Ba, or the like.

Accordingly, both ends of the light emitting element ED may have different polarities. Hereinafter, for convenience of description, an end to which the second semiconductor layer 32 is adjacent among both ends of the light emitting device ED is referred to as a “first end”, and another end to which the first semiconductor layer 31 is adjacent will be referred to as a “second end”. The first end of the light emitting element ED may be positioned opposite to the second end.

It has been illustrated in the drawings that the first semiconductor layer 31 and the second semiconductor layer 32 are configured as one layer, but the disclosure is not limited thereto. The first semiconductor layer 31 and the second semiconductor layer 32 may include a larger number of layers, for example, a clad layer or a tensile strain barrier reducing (TSBR) layer, according to a material of the light emitting layer 36. For example, the light emitting element ED may further include another semiconductor layer disposed between the first semiconductor layer 31 and the light emitting layer 36 or between the second semiconductor layer 32 and the light emitting layer 36. The semiconductor layer disposed between the first semiconductor layer 31 and the light emitting layer 36 may be at least one of AlGaInN, GaN, AlGaN, InGaN, AlN, InN, and SLs doped with an n-type dopant, and the semiconductor layer disposed between the second semiconductor layer 32 and the light emitting layer 36 may be at least one of AlGaInN, GaN, AlGaN, InGaN, AlN, and InN doped with a p-type dopant.

The light emitting layer 36 may be disposed between the first semiconductor layer 31 and the second semiconductor layer 32. The light emitting layer 36 may include a material having a single or multiple quantum well structure. In case that the light emitting layer 36 includes the material having the multiple quantum well structure, the light emitting layer 36 may have a structure in which multiple quantum layers and well layers are alternately stacked each other. The light emitting layer 36 may emit light by a combination of electron-hole pairs according to electrical signals applied through the first semiconductor layer 31 and the second semiconductor layer 32. The light emitting layer 36 may include a material such as AlGaN, AlGaInN, InGaN, or the like. In case that the light emitting layer 36 has the multiple quantum well structure, for example, the structure in which the quantum layers and the well layers are alternately stacked each other, the quantum layers may include a material such as AlGaN or AlGaInN, and the well layers may include a material such as GaN or AlInN.

The light emitting layer 36 may have a structure in which semiconductor materials having a large band gap energy and semiconductor materials having a small band gap energy are alternately stacked each other, and may include Group III to Group V semiconductor materials depending on a wavelength band of emitted light. The light emitted by the light emitting layer 36 is not limited to light of a blue wavelength band, and in some cases, the light emitting layer 36 may emit light of red or green wavelength bands.

For example, the wavelength of light emitted from the light emitting element ED may vary depending on the overall length of the light emitting element ED or the length of the light emitting layer 36. Generally, the longer the overall length of the light emitting element ED or the length of the light emitting layer 36 is, the longer the wavelength of light emitted from the light emitting element ED may be, and the shorter the overall length of the light emitting element ED or the length of the light emitting layer 36 is, the shorter the wavelength of the light emitted from the light emitting element ED may be. The electrode layer 37 may be an ohmic connection electrode. However, the disclosure is not limited thereto, and the electrode layer 37 may be a Schottky connection electrode. The light emitting element ED may include at least one electrode layer 37. The light emitting element ED may include at least one or more electrode layer 37, but the disclosure is not limited thereto, and the electrode layer 37 may be omitted.

The electrode layer 37 may decrease resistance between the light emitting element ED and the electrode or the connection electrode in case that the light emitting element ED is electrically connected to the electrode or the connection electrode in the display device 1. The electrode layer 37 may include a metal having conductivity. For example, the electrode layer 37 may include at least one of aluminum (Al), titanium (Ti), indium (In), gold (Au), silver (Ag), indium tin oxide (ITO), indium zinc oxide (IZO), and indium tin zinc oxide (ITZO). Due to the configuration as described above, both ends of each of the light emitting devices ED may have different polarities.

The insulating layer 38 may be disposed to surround outer surfaces of the semiconductor layers and the electrode layer described above. For example, the insulating layer 38 may be disposed to surround at least an outer surface of the light emitting layer 36, and may be formed to expose both ends of the light emitting element ED in a length direction. The insulating layer 38 may be formed so that a top surface thereof is rounded in cross section in an area adjacent to at least one end of the light emitting element ED.

The insulating layer 38 may include materials having insulating properties, for example, at least one of silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ). It has been illustrated in the drawings that the insulating layer 38 is formed as a single layer, but the disclosure is not limited thereto, and in some embodiments, the insulating layer 38 may also be formed in a multilayer structure in which multiple layers are stacked each other.

The insulating layer 38 may serve to protect the semiconductor layers and the electrode layer of the light emitting element ED. The insulating layer 38 may prevent an electrical short that may occur in the light emitting layer 36 in case that the light emitting layer 36 is in direct contact with an electrode through which an electrical signal is transferred to the light emitting element ED. The insulating layer 38 may prevent a decrease in luminous efficiency of the light emitting element ED.

An outer surface of the insulating layer 38 may be surface-treated. The light emitting elements ED may be sprayed onto the electrode in a state of being dispersed in an ink to be aligned. In order to maintain in a state in which the light emitting elements ED are dispersed without being clustered with other adjacent light emitting elements ED in the ink, a hydrophobic or hydrophilic treatment may be performed on a surface of the insulating layer 38.

Referring to FIGS. 3 to 5, light emitting elements ED emitting different lights from each other may be disposed in the emission area EMA in one pixel PX of the display device 1 according to one embodiment. For example, the light emitting element ED may include a first light emitting element ED_R emitting red light having a peak wavelength in a range of about 610 nm to about 650 nm, a second light emitting element ED_G emitting green light having a peak wavelength in a range of about 510 nm to about 550 nm, and a third light emitting element ED_B emitting blue light having a peak wavelength in a range of about 440 nm to about 480 nm.

A length L1 of the first light emitting element ED_R may be greater than a length L2 of the second light emitting element ED_G, and the length L2 of the second light emitting element ED_G may be greater than a length L3 of the third light emitting element ED_B in the first direction DR1 according to the correlation between the above-described length of the light emitting element ED and the wavelength of light emitted from the light emitting element ED. For example, the length L1 of the first light emitting element ED_R may be in a range of about 6.5 μm to about 7 μm, the length L2 of the second light emitting element ED_G may be in a range of about 5.5 μm to about 6 μm, and the length L3 of the third light emitting element ED_B may be in a range of about 3.8 μm to about 4.9 μm.

The first light emitting element ED_R may be disposed in a space between the first alignment electrode RME1 and the second alignment electrode RME2, for example, on the first yarn path EP1, the second light emitting element ED_G may be disposed in a space between the third alignment electrode RME3 and the fourth alignment electrode RME4, for example, on the second yarn path EP2, and the third light emitting element ED_B may be disposed in a space between the fifth alignment electrode RME5 and the sixth alignment electrode, for example, on the third yarn path EP3.

Since the length L1 of the first light emitting element ED_R is greater than the length L2 of the second light emitting element ED_G and the length L2 of the second light emitting element ED_G is greater than the length L3 of the third light emitting element ED_B, the first alignment electrode RME1 and the second alignment electrode RME2 may be spaced apart by a first width W1, the third alignment electrode RME3 and the fourth alignment electrode RME4 may be spaced apart by a second width W2, and the fifth alignment electrode RME5 and the sixth alignment electrode RME6 may be spaced apart by a third width W3 as described above.

The length L1 of the first light emitting element ED_R may be greater than the first width W1 that is a distance between the first alignment electrode RME1 and the second alignment electrode RME2, the length L2 of the second light emitting element ED_G may be greater than the second width W2 that is a distance between the third alignment electrode RME3 and the fourth alignment electrode RME4, and the length L3 of the third light emitting element ED_B may be greater than the third width W3 that is a distance between the fifth alignment electrode RME5 and the sixth alignment electrode RME6.

As described above, by adjusting the space between the alignment electrodes RME according to the length of the light emitting element ED, the light emitting element ED may be stably aligned in the manufacturing process of the display device 1 to be described later, and the alignment electrodes RME may be effectively arranged in the emission area EMA having a constant width in the first direction DR1. The connection electrodes CNE may be disposed on the alignment electrode RME to contact both ends of the light emitting element ED. Like the alignment electrodes RME, the connection electrodes CNE may cross the emission area EMA in the second direction DR2 and be spaced apart from each other.

The connection electrode CNE may be disposed on the light emitting elements ED. The connection electrode CNE may include a first connection electrode layer CNEL1 and a second connection electrode layer CNEL2. The first connection electrode layer CNEL1 and the second connection electrode layer CNEL2 may be distinguished according to the stacked order. For example, in the display device manufacturing process, the first connection electrode layer CNEL1 may be formed before the second connection electrode layer CNEL2. The stacking relationship of the first connection electrode layer CNEL1 and the second connection electrode layer CNEL2 will be described later.

The first connection electrode layer CNEL1 may include a first connection electrode CNE1 disposed in the first emission portion LP1, a third connection electrode CNE3 disposed in the second emission portion LP2, and a fifth connection electrode CNE5 disposed in the third emission portion LP3. The second connection electrode layer CNEL2 may include a second connection electrode CNE2 disposed in the first emission portion LP1, a fourth connection electrode CNE4 disposed in the second emission portion LP2, and a sixth connection electrode CNE6 disposed in the third emission portion LP3.

The first connection electrode CNE1 may be disposed on the first alignment electrode RME1. A portion of the first connection electrode CNE1 may be connected to the first alignment electrode RME1 through a first contact portion CT1 that does not overlap the emission area EMA, and another portion of the first connection electrode CNE1 may be electrically connected to the first end of the first light emitting element ED_R in the emission area EMA. Accordingly, the first connection electrode CNE1 may receive the above-described first power voltage through the first alignment electrode RME1.

The second connection electrode CNE2 may be disposed on the second alignment electrode RME2. A portion of the second connection electrode CNE2 may be connected to the second alignment electrode RME2 through a second contact portion CT2 that does not overlap the emission area EMA, and another portion of the second connection electrode CNE2 may be electrically connected to the second end of the first light emitting element ED_R in the emission area EMA. Accordingly, the second connection electrode CNE2 may receive the above-described second power voltage through the second alignment electrode RME2.

The third connection electrode CNE3 may be disposed on the third alignment electrode RME3. A portion of the third connection electrode CNE3 may be connected to the third alignment electrode RME3 through a third contact portion CT3 that does not overlap the emission area EMA, and another portion of the third connection electrode CNE3 may be electrically connected to the first end of the second light emitting element ED_G in the emission area EMA. Accordingly, the third connection electrode CNE3 may receive the above-described first power voltage through the third alignment electrode RME3.

The fourth connection electrode CNE4 may be disposed on the fourth alignment electrode RME4. A portion of the fourth connection electrode CNE4 may be connected to the fourth alignment electrode RME4 through a fourth contact portion CT4 that does not overlap the emission area EMA, and another portion of the fourth connection electrode CNE4 may be electrically connected to the second end of the second light emitting element ED_G in the emission area EMA. Accordingly, the fourth connection electrode CNE4 may receive the above-described second power voltage through the fourth alignment electrode RME4.

The fifth connection electrode CNE5 may be disposed on the fifth alignment electrode RME5. A portion of the fifth connection electrode CNE5 may be connected to the fifth alignment electrode RME5 through a fifth contact portion CT5 that does not overlap the emission area EMA, and another portion of the fifth connection electrode CNE5 may be electrically connected to the first end of the third light emitting element ED_B in the emission area EMA. Accordingly, the fifth connection electrode CNE5 may receive the above-described first power voltage through the fifth alignment electrode RME5.

The sixth connection electrode CNE6 may be disposed on the sixth alignment electrode RME6. A portion of the sixth connection electrode CNE6 may be connected to the sixth alignment electrode RME6 through a sixth contact portion CT6 that does not overlap the emission area EMA, and another portion of the sixth connection electrode CNE6 may be electrically connected to the second end of the third light emitting element ED_B in the emission area EMA. Accordingly, the sixth connection electrode CNE6 may receive the above-described second power voltage through the sixth alignment electrode RME6.

The first alignment electrode RME1, the second alignment electrode RME2, the first light emitting element ED_R, the first connection electrode CNE1, and the second connection electrode CNE2 may form the first emission portion LP1. The third alignment electrode RME3, the fourth alignment electrode RME4, the second light emitting element ED_G, the third connection electrode CNE3, and the fourth connection electrode CNE4 may form the second emission portion LP2. The fifth alignment electrode RME5, the sixth alignment electrode RME6, the third light emitting element ED_B, the fifth connection electrode CNE5, and the sixth connection electrode CNE6 may form the third emission portion LP3.

As described above, in the display device 1 according to one embodiment, since one driving circuit is disposed in each light emission portion LPn (refer to FIG. 2), three driving circuits may be disposed in one pixel PX. Accordingly, the first light emitting element ED_R, the second light emitting element ED_G, and the third light emitting element ED_B may be driven by a separate driving circuit.

Hereinafter, a stacked structure of elements constituting one pixel PX of the display device 1 according to one embodiment will be described in detail.

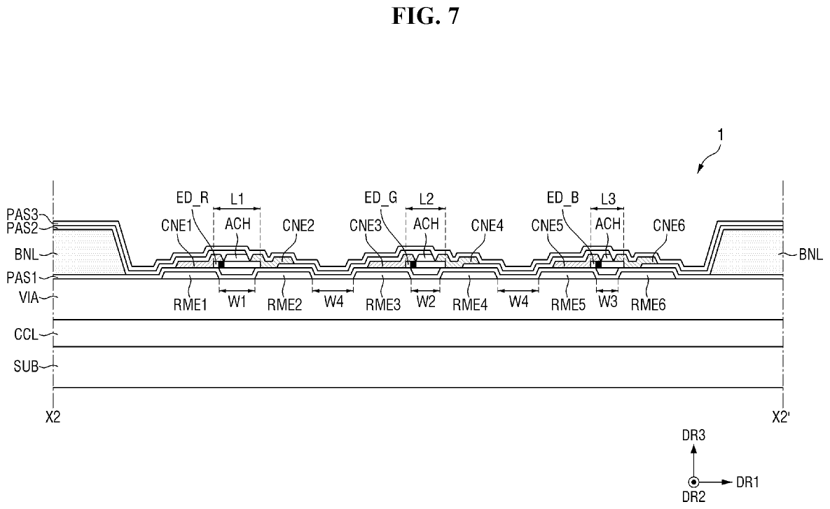

FIG. 6 is a schematic cross-sectional view of a pixel taken along line X1-X1′ of FIG. 5. FIG. 7 is a schematic cross-sectional view of a pixel taken along line X2-X2′ of FIG. 5.

FIG. 6 shows a cross section passing through both ends of the electrode contact holes CTD1 and CTS1, the contact portions CT1 and CT2 and the first light emitting element ED_R. FIG. 7 shows a cross section passing through the first light emitting element ED_R, the second light emitting element ED_G, and the third light emitting element ED_B.

A cross-section crossing the third electrode contact hole CTD2, the fourth electrode contact hole CTS2, the third contact portion CT3, the fourth contact portion CT4, and the second light emitting element ED_G, and a cross-section crossing the fifth electrode contact hole CTD3, the sixth electrode contact hole CTS3, the fifth contact portion CT5, the sixth contact portion CT6, and the third light emitting element ED_B is substantially the same as the cross-section of FIG. 6. Therefore, a description thereof will be omitted, and description will be made with reference to FIG. 6.

Referring to FIGS. 6 to 7, the cross-sectional structure of the display device 1 according to one embodiment will be described. The display device 1 may include a substrate SUB, and a semiconductor layer, multiple conductive layers, and multiple insulating layers disposed on the substrate SUB. The display device 1 may include multiple alignment electrodes RME, light emitting elements ED, and connection electrodes CNE. The semiconductor layer, the conductive layers, and the insulating layers may form a circuit element layer CCL of the display device 1.

The substrate SUB may be made of an insulating material such as glass, quartz, and a polymer resin. The substrate SUB may be either a rigid substrate or a flexible substrate that can be bent, folded, or rolled.

The circuit element layer CCL may be disposed on the substrate SUB. Various wirings transmitting electrical signal to the light emitting element ED disposed on the substrate SUB may be disposed in the circuit element layer CCL. As shown in FIGS. 6 and 7, as conductive layers, the circuit element layer CCL may include a first conductive layer, a semiconductor layer, a second conductive layer, a third conductive layer, and the like, and as insulating layers, the circuit element layer CCL may include a buffer layer BL, a first gate insulating layer GI, a first interlayer insulating layer ILL a first passivation layer PV1, and the like.

A first conductive layer may be disposed on the substrate SUB. The first conductive layer may include a lower metal layer BML, and the lower metal layer BML is disposed to overlap a first active layer ACT1 of the first transistor T1. The lower metal layer BML may prevent light from being incident on the first active layer ACT1 of the first transistor T1 and/or may be electrically connected to the first active layer ACT1 to perform a function of stabilizing electrical characteristics of the first transistor T1. However, the lower metal layer BML may be omitted.

A buffer layer BL may be disposed on the lower metal layer BML and the substrate SUB. The buffer layer BL may be formed on the substrate SUB to protect the transistors of the pixel PX from moisture permeating through the substrate SUB which is vulnerable to moisture permeation, and may perform a surface planarization function.

The semiconductor layer may be disposed on the buffer layer BL. The semiconductor layer may include a first active layer ACT1 of the first transistor T1 and a second active layer ACT2 of the second transistor T2. The first active layer ACT1 and the second active layer ACT2 may be disposed to partially overlap a first gate electrode G1 and a second gate electrode G2 of a second conductive layer respectively to be described later.

The semiconductor layer may include polycrystalline silicon, single crystal silicon, an oxide semiconductor, or the like. In another embodiment, the semiconductor layer may include polycrystalline silicon. The oxide semiconductor may be an oxide semiconductor containing indium (In). For example, the oxide semiconductor may include at least one of indium tin oxide (ITO), indium zinc oxide (IZO), indium gallium oxide (IGO), indium zinc tin oxide (IZTO), indium gallium tin oxide (IGTO), indium gallium zinc oxide (IGZO), and indium gallium zinc tin oxide (IGZTO).

It is illustrated in the drawing that the first transistor T1 and the second transistor T2 are disposed in the pixel PX of the display device 1, but the disclosure is not limited thereto, and the display device 1 may include a larger number of transistors.

A first gate insulating layer GI may be disposed on the semiconductor layer in the display area DA. The first gate insulating layer GI may serve as a gate insulating layer of each of the transistors T1 and T2. It has been illustrated in the drawing that the first gate insulating layer GI is patterned together with gate electrodes G1 and G2 of a second conductive layer to be described later, and is partially disposed between the second conductive layer and the active layers ACT1 and ACT2 of the semiconductor layer. However, the disclosure is not limited thereto. In some embodiments, the first gate insulating layer GI may be entirely disposed on the buffer layer BL.

A second conductive layer may be disposed on the first gate insulating layer GI. The second conductive layer may include a first gate electrode G1 of the first transistor T1 and a second gate electrode G2 of the second transistor T2. The first gate electrode G1 may be disposed to overlap a channel area of the first active layer ACT1 in the third direction DR3, which is the thickness direction, and the second gate electrode G2 may be disposed to overlap a channel area of a second active layer ACT2 in the third direction DR3, which is the thickness direction.

A first interlayer insulating layer IL1 may be disposed on the second conductive layer. The first interlayer insulating layer IL1 may function as an insulating layer between the second conductive layer and other layers disposed thereon, and protect the second conductive layer.

A third conductive layer may be disposed on the first interlayer insulating layer ILL The third conductive layer may include a first voltage wire VL1 and a second voltage wire VL2 disposed in the display area DA, a first conductive pattern CDP1, source electrodes S1 and S2 and drain electrodes D1 and D2 of each transistors T1 and T2, and a second capacitor electrode (not illustrated) of a storage capacitor Cst (see FIG. 2).

A high potential voltage (or a first power voltage) transferred to a first alignment electrode RME1 may be applied to the first voltage wire VL1, and a low potential voltage (or a second power voltage) transferred to a second alignment electrode RME2 may be applied to the second voltage wire VL2. A portion of the first voltage wire VL1 may be in contact with a first active layer ACT1 of the first transistor T1 through a contact hole penetrating through the first interlayer insulating layer IL1. The first voltage wire VL1 may serve as the first drain electrode D1 of the first transistor T1. The first voltage wire VL1 may be directly connected to the first alignment electrode RME1, and the second voltage wire VL2 may be directly connected to the second alignment electrode RME2.

The first conductive pattern CDP1 may be in contact with the first active layer ACT1 of the first transistor T1 through a contact hole penetrating through the first interlayer insulating layer ILL The first conductive pattern CDP1 may be in contact with the lower metal layer BML through another contact hole penetrating through the first interlayer insulating layer IL1 and the buffer layer BL. The first conductive pattern CDP1 may serve as the first source electrode S1 of the first transistor T1. Also, the first conductive pattern CDP1 may be connected to a first electrode RME1 or a first connection electrode CNE1 to be described later. The first transistor T1 may transfer the first power voltage applied from the first voltage wire VL1 to the first electrode RME1 or the first connection electrode CNE1.

The second source electrode S2 and the second drain electrode D2 may each contact the second active layer ACT2 of the second transistor T2 through the contact holes penetrating through the first interlayer insulating layer IL1.

A first passivation layer PV1 may be disposed on the third conductive layer. The first passivation layer PV1 may perform a function of an insulating film between the third conductive layer and other layers, and may protect the third conductive layer.

The buffer layer BL, the first gate insulating layer GI, the first interlayer insulating layer ILL and the first passivation layer PV1 described above may be formed of multiple inorganic layers alternately stacked each other. For example, the buffer layer BL, the first gate insulating layer GI, the first interlayer insulating layer ILL and the first passivation layer PV1 may be formed of a double layer in which inorganic layers each including at least one of silicon oxide (SiOₓ), silicon nitride (SiNₓ), and silicon oxynitride (SiOₓN_{y}) are stacked each other, or multiple layers in which the inorganic layers are alternately stacked each other.

A via insulating layer VIA may be disposed on the circuit element layer CCL. For example, the via insulating layer VIA may be disposed on the first passivation layer PV1 of the circuit element layer CCL. The via insulating layer VIA may include an organic insulating material such as polyimide, to compensate for a step caused by various wirings inside the circuit element layer CCL and to form a flat top surface.

The alignment electrodes RME may be disposed on the top surface of the via insulating layer VIA. In some embodiments, the alignment electrodes RME may be disposed on a planar profile of the via insulating layer VIA with the same thickness. For example, the alignment electrodes RME may have a flat shape (or profile) in the emission area in a cross-sectional view. The bottom surface of each of the alignment electrodes RME may completely contact the top surface of the via insulating layer VIA. In other words, a separate device may not be disposed between the alignment electrode RME and the via insulating layer VIA, but the disclosure is not limited thereto. In case that a separate device is not disposed between the alignment electrode RME and the via insulating layer VIA, the arrangement of devices disposed in one pixel PX of the display device 1 may be simplified. FIG. 6 illustrates that a separate device is not disposed between the alignment electrode RME and the via insulating layer VIA.

As illustrated in FIG. 6, the first alignment electrode RME1 may be in contact with the first conductive pattern CDP1 through the first electrode contact hole CTD1 penetrating the via insulating layer VIA and the first passivation layer PV1, and the second alignment electrode RME2 may be in contact with the second voltage wire VL2 through the second electrode contact hole CTS1 penetrating the via insulating layer VIA and the first passivation layer PV1.

The alignment electrode RME may reflect light emitted from the light emitting element ED. For example, light emitted from the light emitting elements ED may be directed toward the alignment electrode RME. Accordingly, light emitted from the light emitting element ED may be reflected by the alignment electrode RME and emitted in the third direction DR3.

The alignment electrodes RME may include a conductive material having high reflectivity. For example, the alignment electrodes RME may include a metal such as silver (Ag), copper (Cu), aluminum (Al), or the like, or may include an alloy including aluminum (Al), nickel (Ni), lanthanum (La), or may have a stacked structure of metal such as titanium (Ti), molybdenum (Mo), niobium (Nb), or an alloy thereof. In some embodiments, the alignment electrodes RME may be formed of a double or multiple layers in which an alloy including aluminum (Al) and one or more metal layers made of titanium (Ti), molybdenum (Mo), and niobium (Nb) are stacked each other.

However, the disclosure is not limited thereto, and each of the alignment electrodes RME may include a transparent conductive material. For example, each alignment electrode RME may include a material such as ITO, IZO, or ITZO. In some embodiments, each of the alignment electrodes RME may have a structure in which a transparent conductive material and a metal layer having high reflectivity are stacked in one or more layers, or may be formed as one layer including the transparent conductive material and the metal layer having high reflectivity. For example, each alignment electrode RME may have a stacked structure such as ITO/Ag/ITO, ITO/Ag/IZO, or ITO/Ag/ITZO/IZO.

A first insulating layer PAS1 may be disposed on an entire surface of the via insulating layer VIA and the alignment electrodes RME in the display area DA. The first insulating layer PAS1 may include an insulating material to protect the alignment electrodes RME and simultaneously insulate the different alignment electrodes RME from each other. The first insulating layer PAS1 may be disposed to cover the alignment electrodes RME before the bank layer BNL is formed, and may thus prevent the alignment electrodes RME from being damaged in a process of forming the bank layer BNL. The first insulating layer PAS1 may prevent the light emitting element ED disposed thereon from being damaged by being in direct contact with other members.

In an embodiment, the first insulating layer PAS1 may have a step formed so that a portion of a top surface thereof is recessed between the alignment electrodes RME spaced apart from each other in the first direction DR1. The light emitting element ED may be disposed on the top surface of the first insulating layer PAS1 in which the step is formed, and a space may be formed between the light emitting element ED and the first insulating layer PAS1.

The first insulating layer PAS1 may include contact portions CT1 and CT2 as illustrated in FIG. 6. The contact portions may be disposed to overlap different alignment electrodes RME, respectively. For example, the contact portions may include first contact portion CT1 disposed to overlap the first alignment electrode RME1, and second contact portion CT2 disposed to overlap the second alignment electrode RME2 in the third direction DR3. The first contact portion CT1 and the second contact portion CT2 may penetrate through the first insulating layer PAS1 to expose a portion of a top surface of the first alignment electrode RME1 or the second alignment electrode RME2 on a lower side thereof. Each of the first contact portion CT1 and the second contact portion CT2 may further penetrate through some of other insulating layers disposed on the first insulating layer PAS1. The alignment electrode RME exposed by each of the contact portions may be in contact with the connection electrode CNE.

The bank layer BNL may be disposed on the first insulating layer PAS1. In some embodiments, the bank layer BNL may overlap the first electrode contact hole CTD1 or the second electrode contact hole CTS1 in the third direction DR3, but the disclosure is not limited thereto. For example, the bank layer BNL may not overlap the first electrode contact hole CTD1 or the second electrode contact hole CTS1 in the third direction DR3. The bank layer BNL may prevent the ink from overflowing to the adjacent pixel PX in the inkjet printing process during the manufacturing process of the display device 1. The bank layer BNL may include an organic insulating material such as polyimide.

The light emitting elements ED may be disposed on the first insulating layer PAS1. The light emitting elements ED may contact the connection electrodes CNE to be described later to be electrically connected to conductive layers under the alignment electrode RME and the via insulating layer VIA, and an electrical signal may be applied to emit light in a specific wavelength band.

As described above, the first light emitting element ED_R may be disposed in the space between the first alignment electrode RME1 and the second alignment electrode RME2, the second light emitting element ED_G may be disposed in the space between the third alignment electrode RME3 and the fourth alignment electrode RME4, and the third light emitting element ED_B may be disposed in the space between the fifth alignment electrode RME5 and the sixth alignment electrode RME6.

The anchor portion ACH may serve to fix the light emitting element ED. The anchor portion ACH may be disposed on the light emitting elements ED to expose both ends of each of the light emitting elements ED. The anchor portion ACH may include an organic insulating material such as polyimide.

The widths of each of the anchor portions ACH disposed on different light emitting elements ED may be different. For example, the width of the anchor portion ACH disposed on the first light emitting element ED_R may be greater than the width of the anchor portion ACH disposed on the second light emitting element ED_G, and the width of the anchor portion ACH disposed on the second light emitting element ED_G may be greater than the width of the anchor portion ACH disposed on the third light emitting element ED_B in the first direction DR1.

The first connection electrode layer CNEL1 of the connection electrode CNE may be disposed on the first insulating layer PAS1. The first connection electrode layer CNEL1 may include the first connection electrode CNE1, the third connection electrode CNE3, and the fifth connection electrode CNE5.

The first connection electrode CNE1 may be disposed on the first insulating layer PAS1 in the first emission portion LP1 (see FIG. 5) to contact the first light emitting elements ED_R, the third connection electrode CNE3 may be disposed on the first insulating layer PAS1 in the second emission portion LP2 (see FIG. 5) to contact the second light emitting elements ED_G, and the fifth connection electrode CNE5 may be disposed on the first insulating layer PAS1 in the third emission portion LP3 (see FIG. 5) to contact the third light emitting elements ED_B.

The first connection electrode CNE1 may partially overlap the first alignment electrode RME1 in the first emission portion LP1 and may contact the first end of the first light emitting element ED_R. As illustrated in FIG. 6, the first connection electrode CNE1 may partially overlap the first alignment electrode RME1 and may be disposed to extend from the emission area EMA to the bank layer BNL. The first connection electrode CNE1 may contact the first alignment electrode RME1 through the first contact portion CT1 penetrating the first insulating layer PAS1. Accordingly, the first connection electrode CNE1 may be electrically connected to the first transistor T1 to receive the first power voltage.

The third connection electrode CNE3 may partially overlap the third alignment electrode RME3 in the second emission portion LP2. The third connection electrode CNE3 may partially overlap the third alignment electrode RME3 to contact the first end of the second light emitting element ED_G. The third connection electrode CNE3 may receive the first power voltage in a similar manner as the first connection electrode CNE1 contacts the first alignment electrode RME1 through the first contact portion CT1 to receive the first power voltage.

The fifth connection electrode CNE5 may partially overlap the fifth alignment electrode RME5 in the third emission portion LP3. The fifth connection electrode CNE5 may partially overlap the fifth alignment electrode RME5 to contact the first end of the third light emitting element ED_B. The fifth connection electrode CNE5 may receive the first power voltage in a similar manner as the first connection electrode CNE1 contacts the first alignment electrode RME1 through the first contact portion CT1 to receive the first power voltage.

A second insulating layer PAS2 may be disposed on the anchor portion ACH, the first insulating layer PAS1, the bank layer BNL, and the first connection electrode layer CNEL1. The second insulating layer PAS2 may include the second contact portion CT2. For example, the second insulating layer PAS2 may include the second contact portion CT2 disposed to overlap the second alignment electrode RME2. The second contact portion CT2 may pass through the second insulating layer PAS2 in addition to the first insulating layer PAS1. Each of the second contact portions CT2 may expose a portion of a top surface of the second alignment electrode RME2 thereunder.

The second insulating layer PAS2 may not cover an end of the light emitting element ED. In other words, the second insulating layer PAS2 may not cover an end of the light emitting elements ED to which the first connection electrode layer CNEL1 does not contact.

The second connection electrode layer CNEL2 of the connection electrode CNE may be disposed on the second insulating layer PAS2. The second connection electrode layer CNEL2 may include the second connection electrode CNE2, the fourth connection electrode CNE4, and the sixth connection electrode CNE6.

The second connection electrode CNE2 may be disposed on the second insulating layer PAS2 in the first emission portion LP1 (see FIG. 5) to contact the first light emitting elements ED_R, the fourth connection electrode CNE4 may be disposed on the second insulating layer PAS2 in the second emission portion LP2 (see FIG. 5) to contact the second light emitting elements ED_G, and the sixth connection electrode CNE6 may be disposed on the second insulating layer PAS2 in the third emission portion LP3 (see FIG. 5) to contact the third light emitting elements ED_B.

The second connection electrode CNE2 may partially overlap the second alignment electrode RME2 in the first emission portion LP1 and may contact the second end of the first light emitting element ED_R. As illustrated in FIG. 6, the second connection electrode CNE2 may partially overlap the second alignment electrode RME2 and may be disposed to extend from the emission area EMA to the bank layer BNL. The second connection electrode CNE2 may contact the second alignment electrode RME2 through the second contact portion CT2 penetrating the first insulating layer PAS1 and the second insulating layer PAS2. Accordingly, the second connection electrode CNE2 may be electrically connected to a second voltage wire VL2 to receive the second power voltage.

The fourth connection electrode CNE4 may partially overlap the fourth alignment electrode RME4 in the second emission portion LP2. The fourth connection electrode CNE4 may partially overlap the fourth alignment electrode RME4 to contact the second end of the second light emitting element ED_G. The fourth connection electrode CNE4 may receive the second power voltage in a similar manner as the second connection electrode CNE2 contacts the second alignment electrode RME2 through the second contact portion CT2 to receive the second power voltage.

The sixth connection electrode CNE6 may partially overlap the sixth alignment electrode RME6 in the third emission portion LP3. The sixth connection electrode CNE6 may partially overlap the sixth alignment electrode RME6 to contact the second end of the third light emitting element ED_B. The sixth connection electrode CNE6 may receive the second power voltage in a similar manner as the second connection electrode CNE2 contacts the second alignment electrode RME2 through the second contact portion CT2 to receive the second power voltage.

A third insulating layer PAS3 may be disposed on the second insulating layer PAS2. The third insulating layer PAS3 may be disposed in the entire area of the display area DA and may serve to protect the elements constituting the pixel PX from the outside. The third insulating layer PAS3 may be omitted according to some embodiments.

The first insulating layer PAS1, second insulating layer PAS2, and third insulating layer PAS3 described above may each include an inorganic insulating material or an organic insulating material. In an embodiment, each of the first insulating layer PAS1, the second insulating layer PAS2, and the third insulating layer PAS3 may be made of any one of silicon oxide (SiOₓ), silicon nitride (SiNₓ), and silicon oxynitride (SiOₓN_{y}). The first insulating layer PAS1, the second insulating layer PAS2, and the third insulating layer PAS3 may be made of the same material or different materials. In another embodiment, some of them may be made of the same material, and the others may be made of different materials.

Due to the configuration described above, one pixel PX of the display device 1 according to one embodiment may emit red light (i.e., first light) having a peak wavelength in a range of about 610 nm to about 650 nm, green light (i.e., second light) having a peak wavelength in a range of about 510 nm to about 550 nm, and blue light (i.e., third light) having a peak wavelength in a range of about 440 nm to about 480 nm. In other words, light having at least three wavelength bands may be emitted from one light emitting area.

Accordingly, the display device 1 according to one embodiment may reduce the area in which the pixels PX occupy compared to a structure separately including a first light emitting area emitting a first light, a second light emitting area emitting a second light, and a third light emitting area emitting a third light, thereby implementing high-resolution of the display device 1.

Hereinafter, a process for manufacturing the display device 1 according to one embodiment will be described.

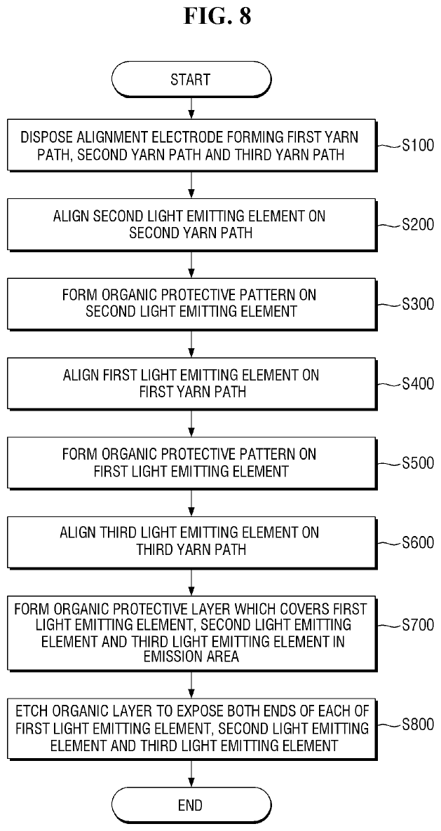

FIGS. 8 through 23 are views for explaining a process for manufacturing a display device according to one embodiment.

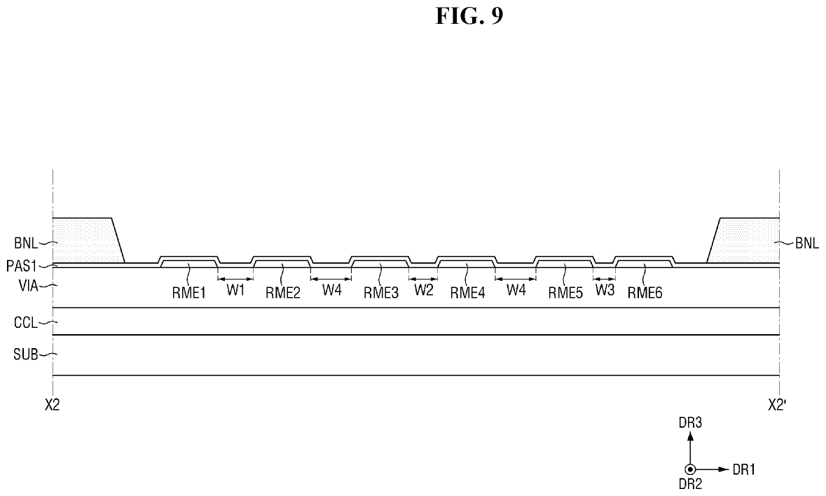

Referring to FIGS. 9 to 23 in conjunction with FIG. 8, the process for manufacturing the display device 1 according to one embodiment may include arranging the alignment electrodes RME forming the first yarn path EP1 (see FIG. 5), the second yarn path EP2 (see FIG. 5), and the third yearn path EP3 (see FIG. 5) (step S100), aligning the second light emitting element ED_G on the second yarn path EP2 (step S200), forming an organic protective pattern PP on the second light emitting element ED_G (step S300), aligning the first light emitting element ED_R on the first yarn path EP1 (step S400), forming an organic protective pattern PP on the first light emitting element ED_R (step S500), aligning the third light emitting element ED_B on the third yarn path EP3 (step S600), forming an organic passivation layer PL which covers the first light emitting element ED_R, the second light emitting element ED_G, and the third light emitting element ED_B in the emission area EMA (see FIG. 5) (step S700), and etching the organic passivation layer PL to expose both ends of each of the first light emitting element ED_R, the second light emitting element ED_G, and the third light emitting element ED_B (step S800).

Referring to FIG. 9, the circuit element layer CCL and the via insulating layer VIA may be formed on the substrate SUB, and the alignment electrodes RME forming the first yarn path EP1 (see FIG. 5), the second yarn path (see FIG. 5), and the third yarn path EP3 (see FIG. 5) may be disposed on the via insulating layer VIA.

A detailed description of forming the circuit element layer CCL and the via insulating layer VIA on the substrate SUB is omitted.

The alignment electrodes RME may be disposed on the via insulating layer VIA, and a separate device may not be disposed between the via insulating layer VIA and the alignment electrodes RME. As described above, the alignment electrode RME may include the first alignment electrode RME1, the second alignment electrode RME2, the third alignment electrode RME3, the fourth alignment electrode RME4, the fifth alignment electrode RME5, and the sixth alignment electrode RME6 arranged sequentially along the first direction DR1. For example, the second alignment electrode RME2 may be disposed on a side of the first alignment electrode RME1 in the first direction DR1, the third alignment electrode RME3 may be disposed on a side of the second alignment electrode RME2 in the first direction DR1, the fourth alignment electrode RME4 may be disposed on a side of the third alignment electrode RME3 in the first direction DR1, the fifth alignment electrode RME5 may be disposed on a side of the fourth alignment electrode RME4 in the first direction DR1, and the sixth alignment electrode RME6 may be disposed on a side of the fifth alignment electrode RME5 in the first direction DR1 spaced apart from each other.

For example, the first alignment electrode RME1 and the second alignment electrode RME2 may be spaced apart by the first width W1 to form a first yarn path EP1, the third alignment electrode RME3 and the fourth alignment electrode RME4 may be spaced apart by the second width W2 to form a second yarn path EP2, and the fifth alignment electrode RME5 and the sixth alignment electrode RME6 may be spaced apart by the third width W3 to form a third yarn path EP3. The first yarn EP1, the second yarn EP2, and the third yarn EP3 may be regions in which the light emitting devices ED are aligned through a subsequent process.

The second alignment electrode RME2 and the third alignment electrode RME3 may be spaced apart in the first direction by the fourth width W4, and the fourth alignment electrode RME4 and the fifth alignment electrode RME5 may be spaced apart in the first direction DR1 by the fourth width W4. The light emitting element ED may not be disposed in the space between the second alignment electrode RME2 and the third alignment electrode RME3 and the space between the fourth alignment electrode RME4 and the fifth alignment electrode RME5.

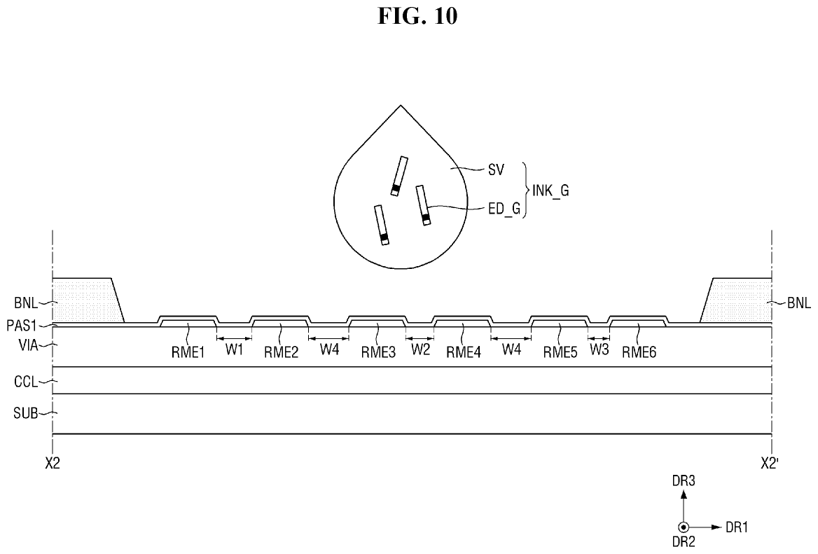

Referring to FIGS. 10 to 12, an alignment signal may be applied to the third alignment electrode RME3 and the fourth alignment electrode RME4 to align the second light emitting elements ED_G discharged to the second yarn path EP2. The process of aligning the second light emitting elements ED_G may be performed using a dielectrophoresis (DEP) force generated by an electric field generated by alignment signals having different potential values.

In the space between the third alignment electrode RME3 and the fourth alignment electrode RME4, a second ink INK_G including a solvent SV and the second light emitting elements ED_G dispersed in the solvent SV may be ejected. The discharge of the second ink INK_G may be performed by an ink-jet printing apparatus. In case that the inkjet printing apparatus discharges the second ink INK_G, the second ink INK_G may be discharged to the area surrounded by the bank layer BNL, for example, the emission area EMA (see FIG. 5).

The alignment signal may include a first alignment signal having a potential value substantially equal to the above-described first power voltage and a second alignment signal having a potential value substantially equal to the above-described second power voltage.

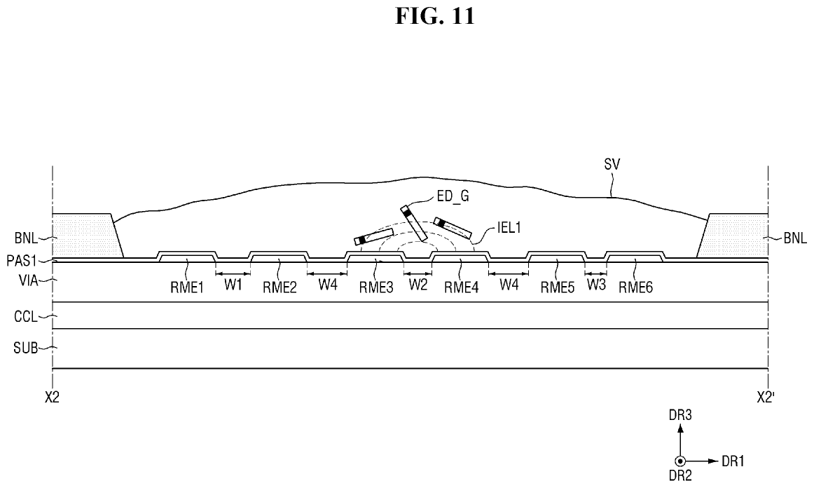

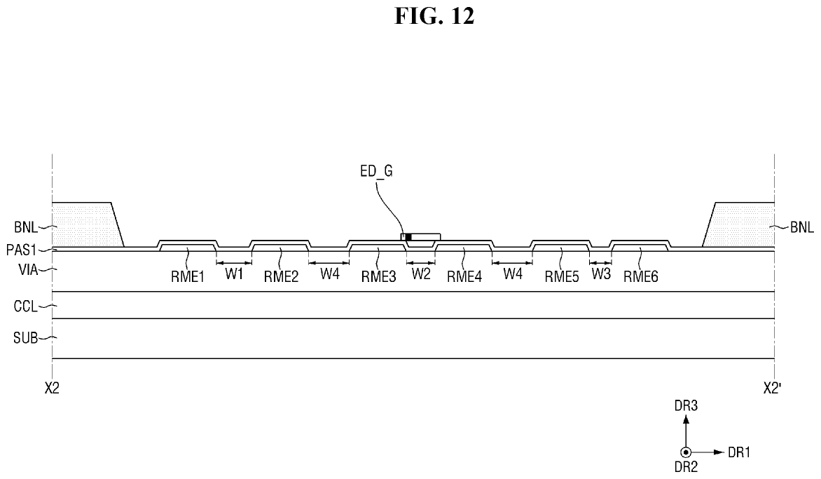

A first electric field IEL1 may be generated by applying the first alignment signal to the third alignment electrode RME3 and applying the second alignment signal to the fourth alignment electrode RME4. Accordingly, as illustrated in FIGS. 11 and 12, the second light emitting element ED_G may be aligned so that the first end is disposed on the third alignment electrode RME3 and the second end is disposed on the fourth alignment electrode RME4 by the first electric field IEL1.

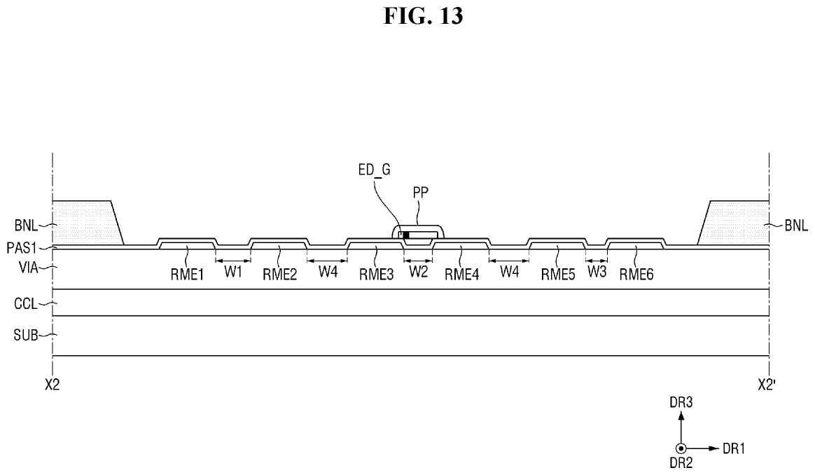

Referring to FIG. 13, an organic protective pattern PP may be formed on the second light emitting element ED_G disposed in a space between the third alignment electrode RME3 and the fourth alignment electrode RME4. The organic protective pattern PP may be formed by coating a photosensitive organic material on the second light emitting element ED_G, and exposing and developing the photosensitive organic material.

The organic protective pattern PP may maintain the state in which the second light emitting element ED_G is aligned, and the second light emitting element ED_G may be prevented from being affected by the first light emitting element ED_R alignment process or the third light emitting element ED_B alignment process.

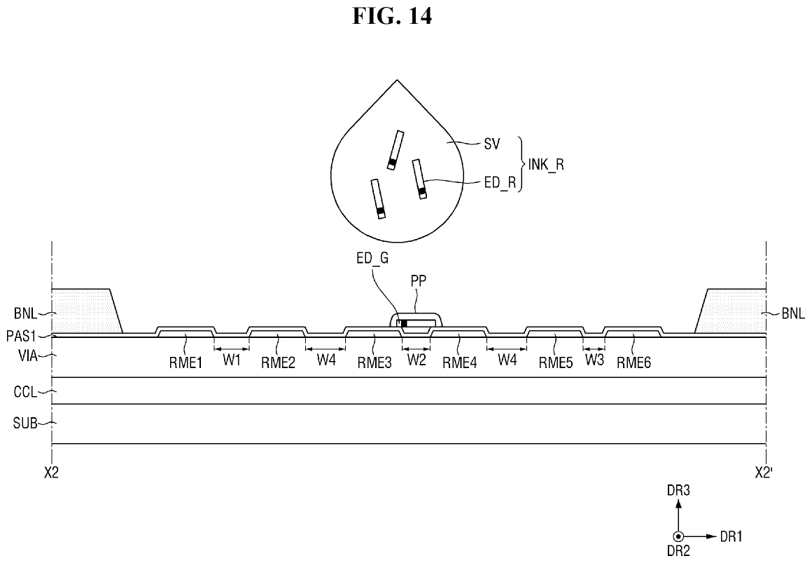

Referring to FIGS. 14 to 16, an alignment signal may be applied to the first alignment electrode RME1 and the second alignment electrode RME2 to align the first light emitting elements ED_R discharged to the first yarn path EP1. The process of aligning the first light emitting elements ED_R is similar to the process of aligning the second light emitting elements ED_G using a dielectrophoretic force generated by an electric field generated by alignment signals having different potential values.

In a space between the first alignment electrode RME1 and the second alignment electrode RME2, a first ink INK_R including a solvent SV and the first light emitting elements ED_R dispersed in the solvent SV may be discharged. The discharge of the first ink INK_R may be performed by an inkjet printing apparatus.

In case that the inkjet printing apparatus discharges the first ink INK_R, the first ink INK_R may be discharged to the area surrounded by the bank layer BNL, for example, the emission area EMA (see FIG. 5). In other words, since the emission area EMA from which the second ink INK_G is discharged is also shared with the area the first ink INK_R is discharged as described in connection with FIGS. 10 to 12, the first ink INK_R may be discharged at substantially the same or similar discharge amount as compared to the discharge amount through which the second ink INK_G is discharged.

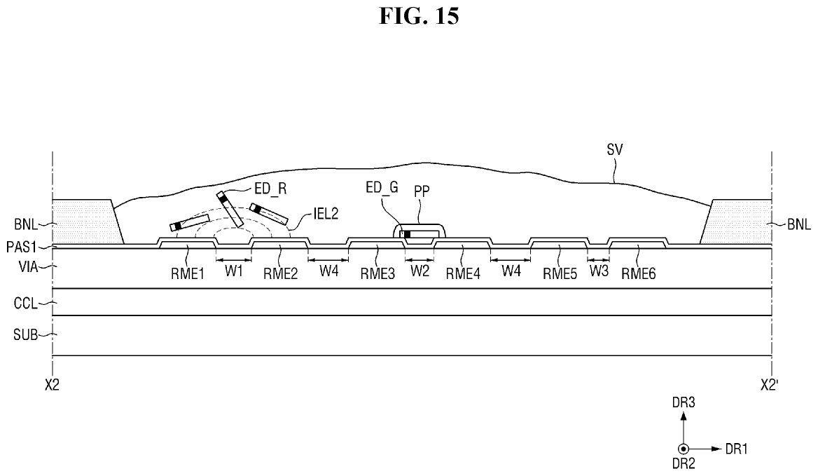

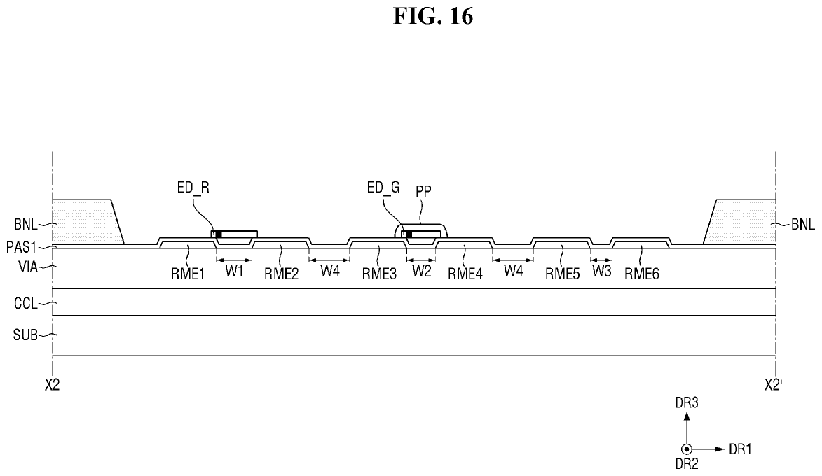

A second electric field IEL2 may be generated by applying the first alignment signal to the first alignment electrode RME1 and applying the second alignment signal to the second alignment electrode RME2. Accordingly, as illustrated in FIGS. 15 and 16, the first light emitting element ED_R may be aligned so that the first end is disposed on the first alignment electrode RME1 and the second end is disposed on the second alignment electrode RME2 by the second electric field IEL2.

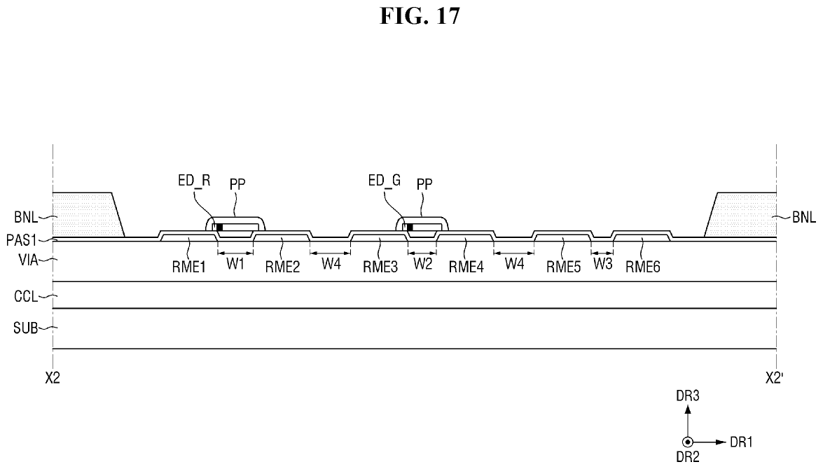

The process for aligning the first light emitting elements ED_R may be readily performed as the organic protective pattern PP disposed on the second light emitting element ED_G induces the first light emitting element ED_R dispersed in the solvent SV to move to the space between the first alignment electrode RME1 and the second alignment electrode RME2. Referring to FIG. 17, an organic protective pattern PP may be formed on the first light emitting element ED_R disposed in a space between the first alignment electrode RME1 and the second alignment electrode RME2. The organic protective pattern PP may be formed by coating a photosensitive organic material on the first light emitting element ED_R, and exposing and developing the photosensitive organic material.

The organic protective pattern PP may maintain a state in which the first light emitting element ED_R is aligned and may prevent the first light emitting element ED_R from being affected by a subsequent third light emitting element ED_B alignment process.

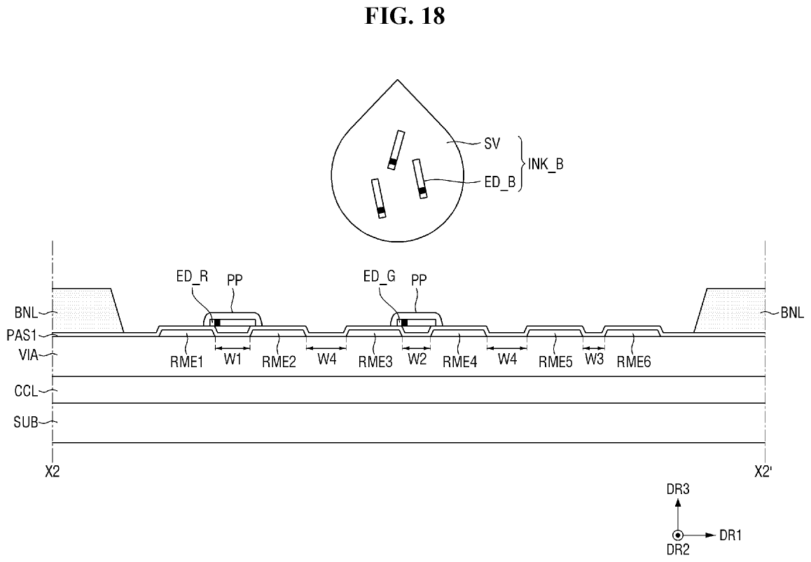

Referring to FIGS. 18 to 20, the alignment signal may be applied to the fifth alignment electrode RME5 and the sixth alignment electrode RME6 to align the third light emitting elements ED_B discharged to the third yarn path EP3. The process of aligning the third light emitting elements ED_B is similar to the process of aligning the second light emitting elements ED_G using a dielectrophoretic force generated by an electric field generated by alignment signals having different potential values.

In a space between the fifth alignment electrode RME5 and the sixth alignment electrode RME6, a third ink INK_B including the solvent SV and third light emitting elements ED_B dispersed in the solvent SV may be discharged. The discharge of the third ink INK_B may be performed by an inkjet printing apparatus.

In case that the inkjet printing apparatus discharges the third ink INK_B, the third ink INK_B may be discharged to the area surrounded by the bank layer BNL, for example, the emission area EMA (see FIG. 5). In other words, since the emission area EMA from which the second ink INK_G is discharged is also shared with the are the third ink INK_B is discharged as described in connection with FIGS. 10 to 12, the third ink INK_B may be discharged at substantially the same or similar discharge amount as compared to the discharge amount through which the second ink INK_G is discharged.

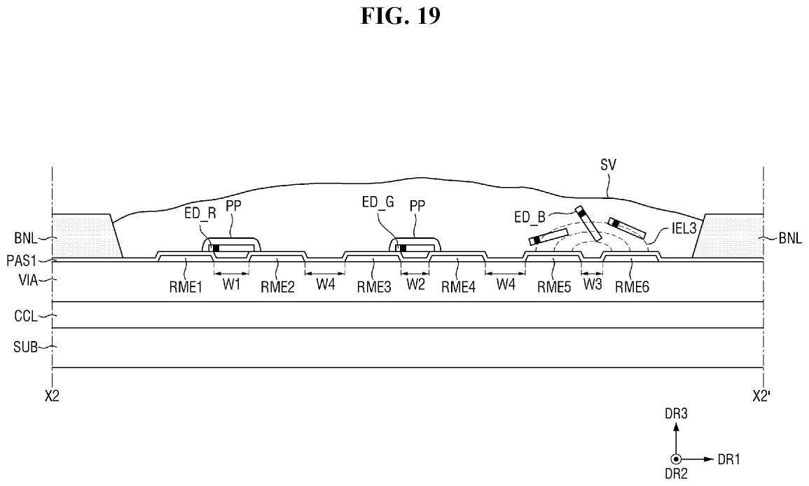

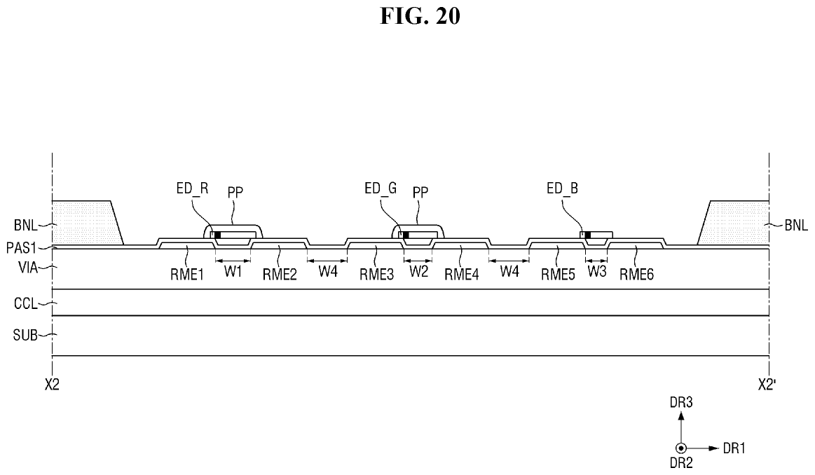

A third electric field IEL3 may be generated by applying the first alignment signal to the fifth alignment electrode RME5 and applying the second alignment signal to the sixth alignment electrode RME6. Accordingly, as illustrated in FIGS. 19 and 20, the third light emitting element ED_B may be aligned so that the first end is disposed on the fifth alignment electrode RME5 and the second end is disposed on the sixth alignment electrode RME6 by the third electric field IEL3.

The process for aligning the third light emitting elements ED_B may be readily performed as the organic protective pattern PP disposed on the second light emitting element ED_G induces the third light emitting element ED_B dispersed in the solvent SV to move to the space between the fifth alignment electrode RME5 and the sixth alignment electrode RME6.

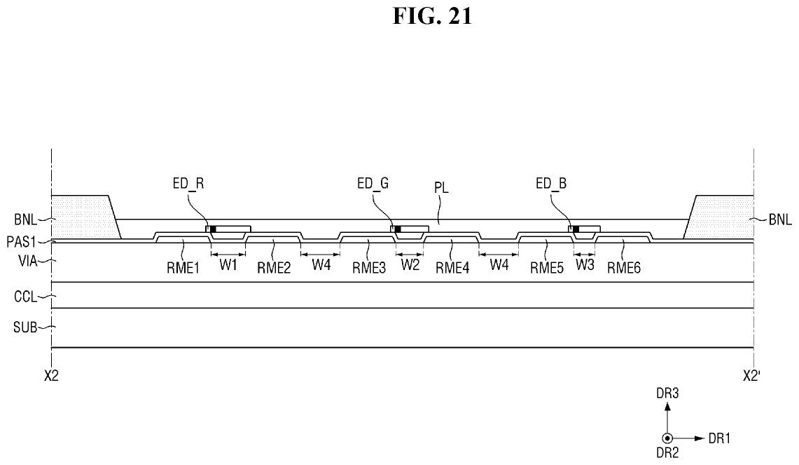

Referring to FIGS. 21 to 23, an organic passivation layer PL covering the first light emitting element ED_R, the second light emitting element ED_G and the third light emitting element ED_B may be formed, and the organic passivation layer PL may be etched to expose both ends of each of the first light emitting element ED_R, the second light emitting element ED_G, and the third light emitting element ED_B. The process of exposing both ends of each of the first light emitting element ED_R, the second light emitting element ED_G, and the third light emitting element ED_B may be performed through dry etching using a mask MASK, but the disclosure is not limited thereto.

As shown in FIG. 21, the organic passivation layer PL may be formed by using the same material as the organic protective pattern PP disposed on the first light emitting element ED_R or the organic protective pattern PP disposed on the second light emitting element ED_G to planarize the area surrounded by the bank layer BNL.

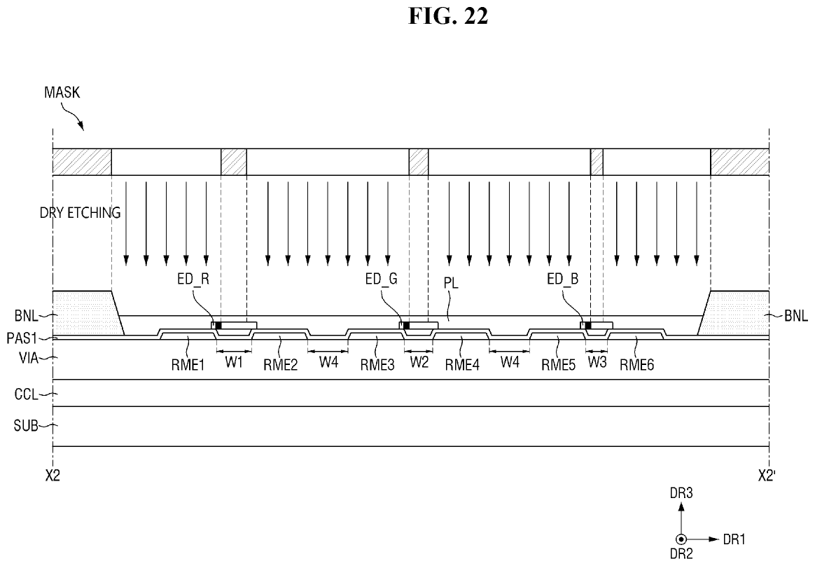

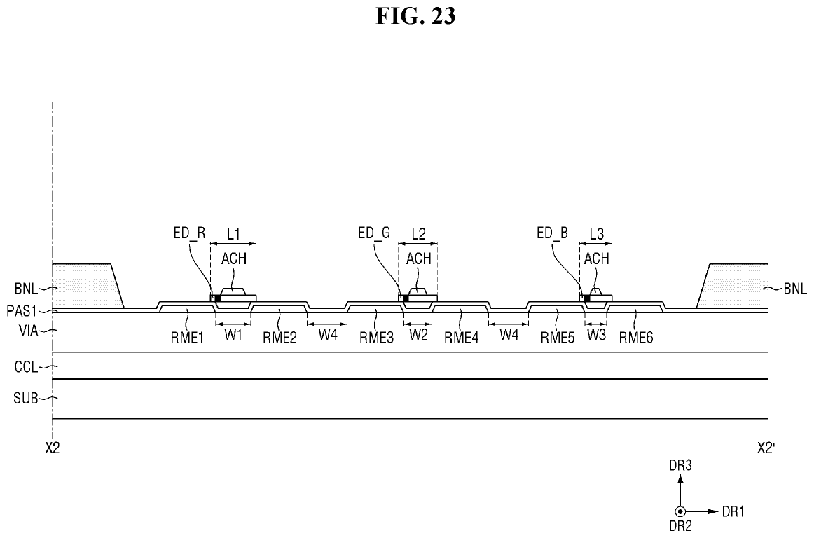

The process of exposing both ends of each of the first light emitting device ED_R, the second light emitting device ED_G, and the third light emitting device ED_B may be performed through dry-etching using the mask MASK as illustrated in FIGS. 22 and 23. The mask MASK may include a shielding portion (hatched area) that is not etched and an etched portion (non-hatched area) corresponding to the width of the anchor portion ACH to be formed on each light emitting element.

Since the organic passivation layer PL is entirely formed in the area surrounded by the bank layer BNL, it is possible to protect elements under the light emitting element ED from an etching process and to stably perform the etching process.

Hereinafter, another embodiment of the display device 1 will be described. In the following embodiments, the same components as those of the above-described embodiment will be denoted by the same reference numerals, and an overlapping description thereof will be omitted or simplified, and differences will be described.

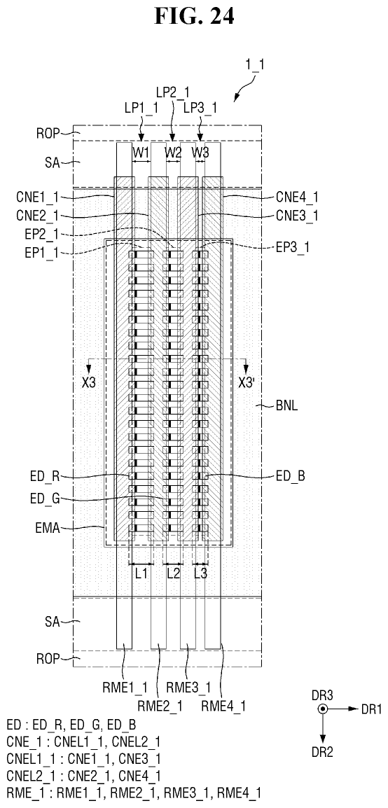

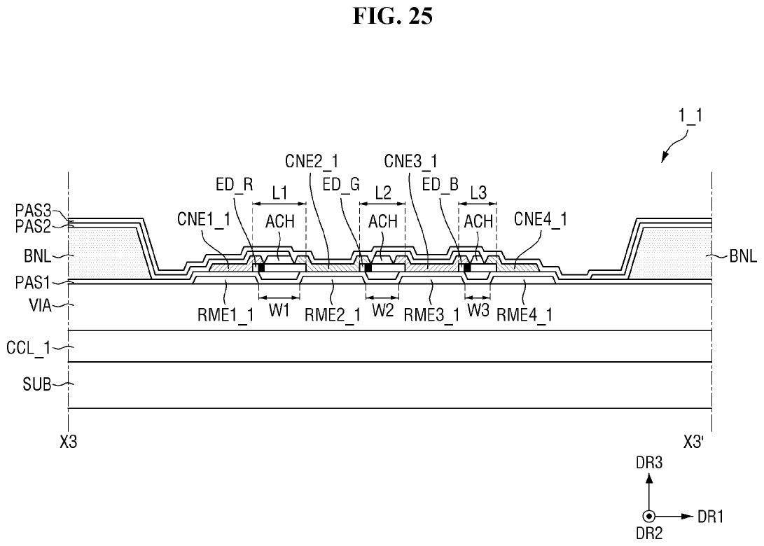

FIG. 24 is a plan view of illustrating a pixel structure of a display device according to another embodiment. FIG. 25 is a schematic cross-sectional view of a pixel taken along line X3-X3′ of FIG. 24.

Referring to FIGS. 24 and 25, one pixel of a display device 1_1 according to the embodiment may have at least one connection electrode CNE_1 among the connection electrodes CNE_1 disposed on the light emitting element ED to be in contact with two light emitting elements ED.

One pixel according to the embodiment may include an alignment electrode RME_1, a light emitting element ED disposed on the alignment electrode RME_1, and a connection electrode CNE_1 disposed on the light emitting element ED.

The alignment electrode RME_1 may include a first alignment electrode RME1_1, a second alignment electrode RME2_1, a third alignment electrode RME3_1, and a fourth alignment electrode RME4_1 sequentially arranged along the first direction DR1. For example, the second alignment electrode RME2_1 may be disposed on a side of the first alignment electrode RME1_1 in the first direction DR1, the third alignment electrode RME3_1 may be disposed on a side of the second alignment electrode RME2_1 in the first direction DR1, and the fourth alignment electrode RME4_1 may be disposed on a side of the third alignment electrode RME3_1 in the first direction DR1.

The first alignment electrode RME1_1, the second alignment electrode RME2_1, the third alignment electrode RME3_1, and the fourth alignment electrode RME4_1 may be spaced apart from each other in the first direction DR1. For example, the first alignment electrode RME1_1 and the second alignment electrode RME2_1 may be spaced apart by a first width W1 in the first direction DR1 to form a first yarn path EP1_1, a second alignment electrode RME2_1 and the third alignment electrode RME3_1 may be spaced apart by a second width W2 in the first direction DR1 to form a second yarn path EP2_1, and the third alignment electrode RME3_1 and the fourth alignment electrode RME4_1 may be spaced apart by a third width W3 in the first direction DR1 to form the third yarn path EP3_1.

The width of the first yarn path EP1_1 in the first direction DR1 may be substantially the same as the first width W1, the width of the second yarn path EP2_1 in the first direction DR1 may be substantially the same as the second width W2, and the width of the third yarn path EP3_1 in the first direction DR1 may be substantially the same as the third width W3. In some embodiments, the first width W1 may be greater than the second width W2, and the second width W2 may be greater than the third width W3, but the disclosure is not limited thereto. In FIG. 24, a configuration in which the first width W1 is greater than the second width W2 and the second width W2 is greater than the third width W3 is illustrated.

The first light emitting element ED_R may be disposed between the first alignment electrode RME1_1 and the second alignment electrode RME2_1, for example, on the first yarn path EP1_1, the second light emitting element ED_G may be disposed between the second alignment electrode RME2_1 and the third alignment electrode RME3_1, for example, on the second yarn path EP2_1, and the third light emitting element ED_B may be disposed between the third alignment electrode RME3_1 and the fourth alignment electrode rme4_1, for example, the third yarn path EP3_1.

For example, the first end of the first light emitting element ED_R may be disposed on a side of the first alignment electrode RME1_1 in the first direction DR1, and the second end of the first light emitting element ED_R may be disposed on another side of the second alignment electrode RME2_1 in the first direction DR1. The first end of the second light emitting element ED_G may be disposed on a side of the second alignment electrode RME2_1 in the first direction DR1, and the second end of the second light emitting element ED_G may be disposed on a side of the third alignment electrode RME3_1 in the first direction DR1. The first end of the third light emitting element ED_B may be disposed on another side of the third alignment electrode RME3_1 in the first direction DR1, and the second end of the third light emitting element ED_B may be disposed on a side of the fourth alignment electrode 4_1 in the first direction DR1.

The connection electrode CNE_1 may be disposed on the light emitting elements ED. The connection electrode CNE_1 may include a first connection electrode layer CNEL1_1 and a second connection electrode layer CNEL2_1. The first connection electrode layer CNEL1_1 and the second connection electrode layer CNEL2_1 may be distinguished according to a stacking order. For example, the first connection electrode layer CNEL1_1 may be formed before the second connection electrode layer CNEL2_1 in the display device manufacturing process.

The first connection electrode layer CNEL1_1 may include a first connection electrode CNE1_1 and a third connection electrode CNE3_1, and the second connection electrode layer CNEL2_1 may include a second connection electrode CNE2_1 and a fourth connection electrode CNE4_1.

The first connection electrode CNE1_1 may be disposed on the first alignment electrode RME1_1 to be electrically connected to a first end of the first light emitting element ED_R. The first connection electrode CNE1_1 may be electrically connected to a separate driving circuit included in the circuit element layer CCL_1 to receive voltages having various potential values.

The second connection electrode CNE2_1 may be disposed on the second alignment electrode RME2_1 to be electrically connected to the second end of the first light emitting element ED_R and the first end of the second light emitting element ED_G. The second connection electrode CNE2_1 may be electrically connected to a separate driving circuit included in the circuit element layer CCL_1 to receive voltages having various potential values.

The third connection electrode CNE3_1 may be disposed on the third alignment electrode RME3_1 to be electrically connected to the second end of the second light emitting element ED_G and the first end of the third light emitting element ED_B. The third connection electrode CNE3_1 may be electrically connected to a separate driving circuit included in the circuit element layer CCL_1 to receive voltages having various potential values.

The fourth connection electrode CNE4_1 may be disposed on the fourth alignment electrode RME4_1 to be electrically connected to the second end of the third light emitting element ED_B. The fourth connection electrode CNE4_1 may be electrically connected to a separate driving circuit included in the circuit element layer CCL_1 to receive voltages having various potential values.

The first alignment electrode RME1_1, the second alignment electrode RME2_1, the first light emitting element ED_R, the first connection electrode CNE1_1, and the second connection electrode CNE2_1 may form a first emission portion LP1_1, the second alignment electrode RME2_1, the third alignment electrode RME3_1, the second light emitting element ED_G, the second connection electrode CNE2_1, and the third connection electrode CNE3_1 may form a second emission portion LP2_1, and the third alignment electrode RME3_1, the fourth alignment electrode RME4_1, the third light emitting element ED_B, the third connection electrode CNE3_1, and the fourth connection electrode CNE4_1 may form a third emission portion LP3_1.

In the display device 1_1 according to the embodiment, a separate driving circuit may be connected to each of the first connection electrode CNE1_1, the second connection electrode CNE2_1, the third connection electrode CNE3_1, and the fourth connection electrode CNE4_1 to drive the first light emitting element ED_R, the second light emitting element ED_G, and the third light emitting element ED_B according to the configuration as described above.

Hereinafter, a method of driving the light emitting elements ED disposed in the pixel of the display device 1_1 according to the embodiment will be described.

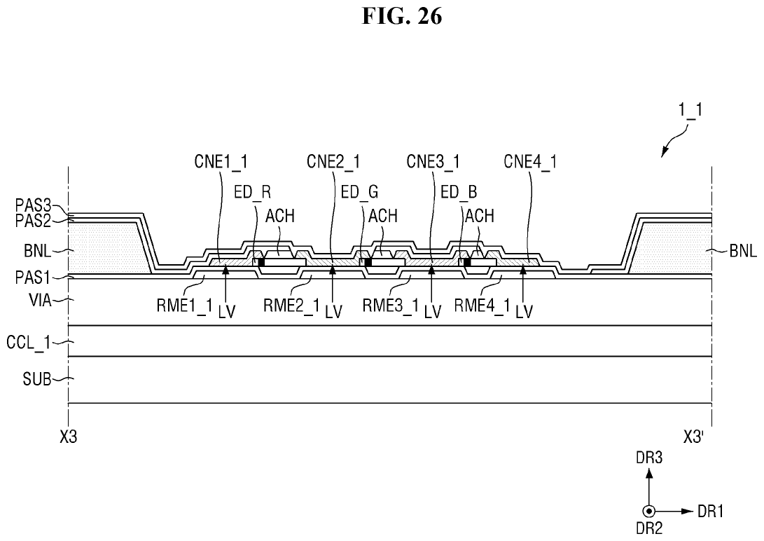

FIGS. 26 through 33 are views for explaining a process for driving light emitting elements of a display device according to embodiment of FIG. 24.

Referring to FIGS. 26 to 33, in case that powers having different potential values are applied to both ends of the light emitting element ED, a first power HV having a relatively high potential may be applied to the first end and a second power LV having a relatively low potential may be applied to the second end. As described above, since a separate driving circuit is connected to each of the connection electrodes CNE_1, power of different potential values may be applied to each of the connection electrodes CNE_1, so that the light emitting elements ED may be individually driven. Although only the first power HV and the second power LV are illustrated in the drawing, power having a potential value different from the potential value of the first power HV and the potential value of the second power LV may be applied. For simplicity of description, the first power HV and the second power LV will be described.

As illustrated in FIG. 26, in case that the second power LV is applied to all of the first connection electrode CNE1_1, the second connection electrode CNE2_1, the third connection electrode CNE3_1, and the fourth connection electrode CNE4_1, the first power HV may be not applied to any one of the first light emitting element ED_R, the second light emitting element ED_G, and the third light emitting element ED_B. Therefore, all of the first light emitting element ED_R, the second light emitting element ED_G, and the third light emitting element ED_B may not emit light, and thus black may be expressed.

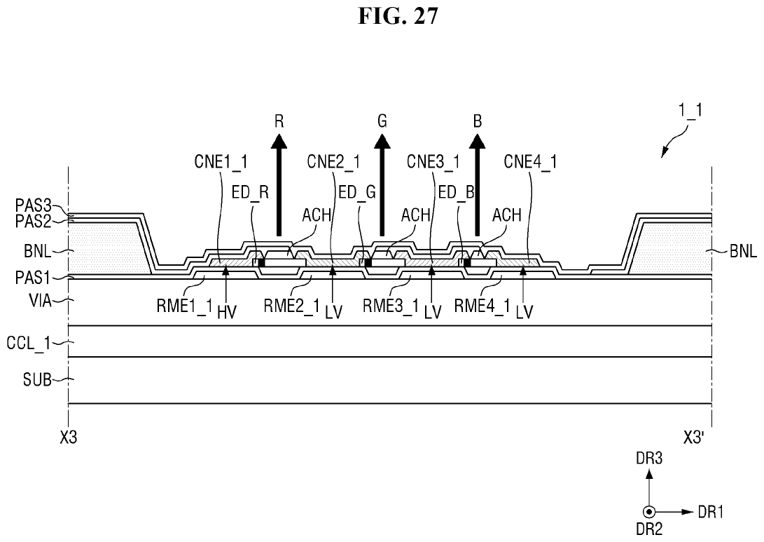

As illustrated in FIG. 27, in case that the first power HV is applied to the first connection electrode CNE1_1 and the second power LV is applied to the second connection electrode CNE2_1, the third connection electrode CNE3_1, and the fourth connection electrode CNE4_1, the first power HV may be applied to each of the first ends of the first connection electrode CNE1_1, second connection electrode CNE2_1, and third connection electrode CNE3_1, and the second power LV may be applied to the second ends so that all of the first light emitting element ED_R, the second light emitting element ED_G, and the third light emitting element ED_B may emit light. Accordingly, white may be expressed.

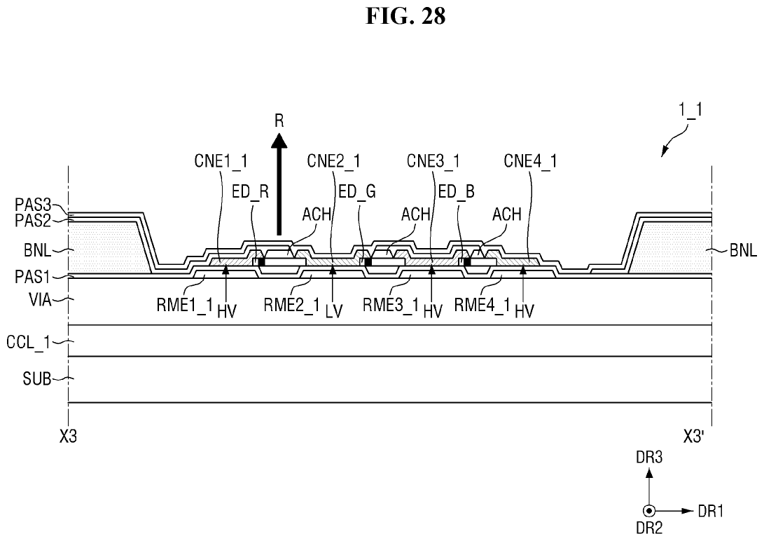

As illustrated in FIG. 28, in case that the first power HV is applied to the first connection electrode CNE1_1 and the third connection electrode CNE3_1, and the second power LV is applied to the second connection electrode CNE2_1 and the fourth connection electrode CNE4_1, the first power HV may be applied only to the first end of the first light emitting element ED_R and the second power LV may be applied to the second end. Accordingly, only the first light emitting element ED_R may emit light to express red R.

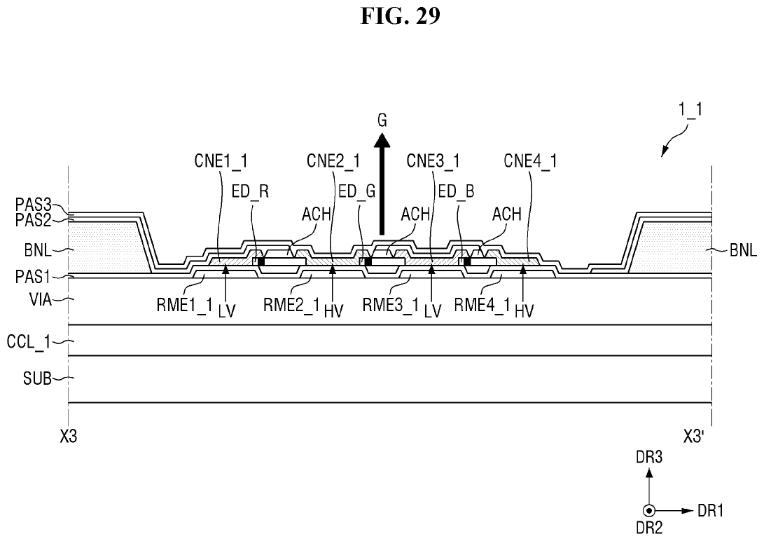

As illustrated in FIG. 29, in case that the second power LV is applied to the first connection electrode CNE1_1 and the third connection electrode CNE3_1, and the first power HV is applied to the second connection electrode CNE2_1 and the fourth connection electrode CNE4_1, the first power HV may be applied only to the first end of the second light emitting element ED_G, and the second power LV may be applied to the second end. Accordingly, only the second light emitting element ED_G may emit light to express green G.

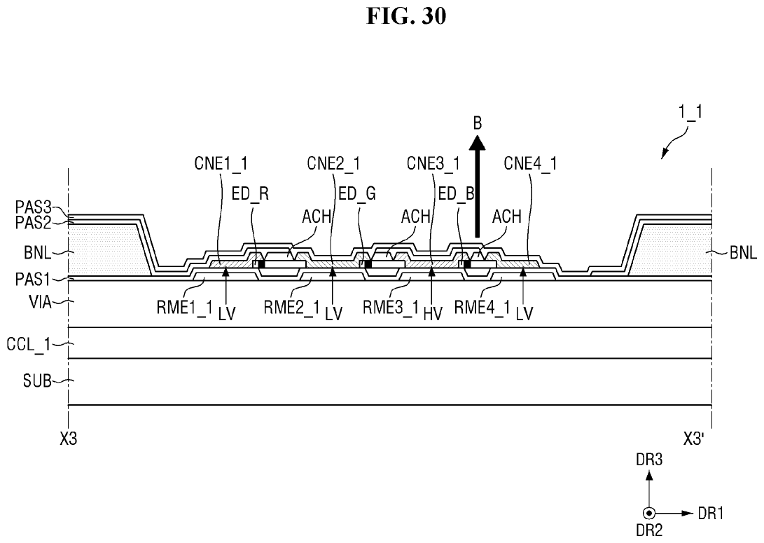

As illustrated in FIG. 30, in case that the second power LV is applied to the first connection electrode CNE1_1, the second connection electrode CNE2_1, and the fourth connection electrode CNE4_1, and the first power HV is applied to the third connection electrode CNE3_1, the first power HV may be applied only to the first end of the third light emitting element ED_B, and the second power LV may be applied to the second end. Accordingly, only the third light emitting element ED_B may emit light to express blue B.

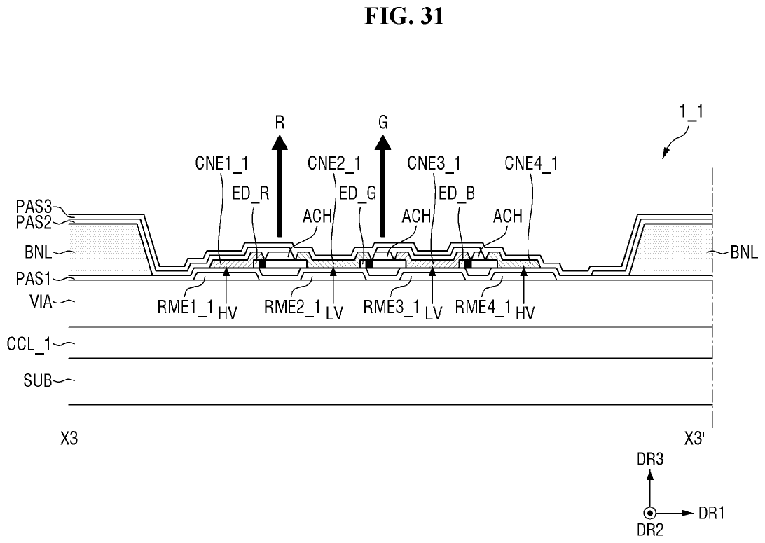

As illustrated in FIG. 31, in case that the first power HV is applied to the first connection electrode CNE1_1 and the fourth connection electrode CNE4_1, and the second power LV is applied to the second connection electrode CNE2_1 and the third connection electrode CNE3_1, the first power HV may be applied to the first end of each of the first light emitting element ED_R and the second light emitting element ED_G, and the second power LV may be applied to the second ends. Accordingly, the first light emitting element ED_R and the second light emitting element ED_G may emit light.

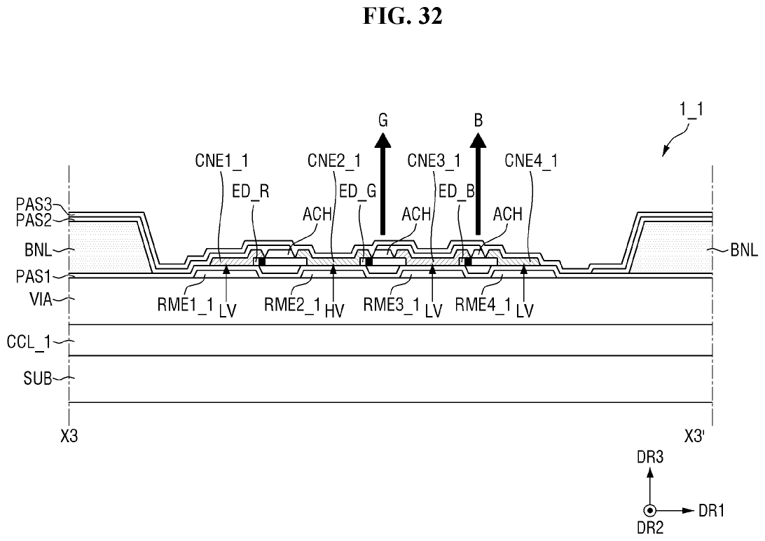

As illustrated in FIG. 32, in case that the second power LV is applied to the first connection electrode CNE1_1, the third connection electrode CNE3_1, and the fourth connection electrode CNE4_1, and the first power HV is applied to the second connection electrode CNE2_1, the first power HV may be applied to the first end of each of the second light emitting element ED_G and the third light emitting element ED_B, and the second power LV may be applied to the second ends. Accordingly, the second light emitting element ED_G and the third light emitting element ED_B may emit light.

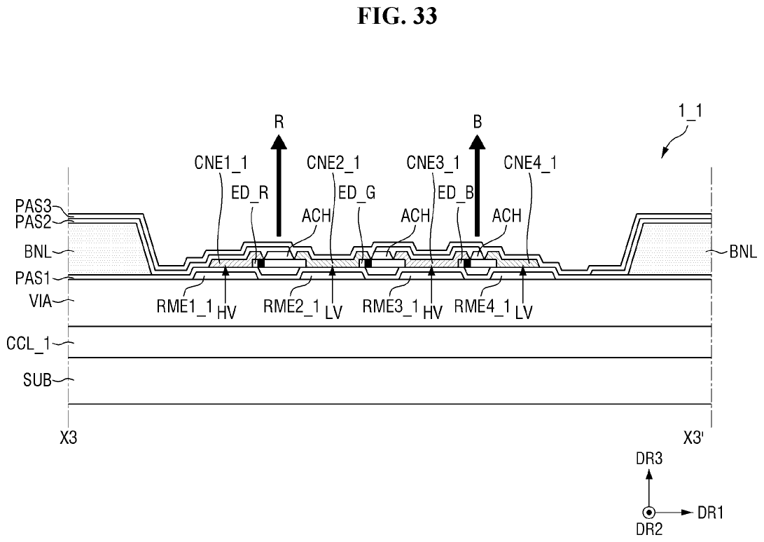

As illustrated in FIG. 33, in case that the first power HV is applied to the first connection electrode CNE1_1 and the third connection electrode CNE3_1, and the second power LV is applied to the second connection electrode CNE2_1 and the fourth connection electrode CNE4_1, the first power HV may be applied to the first end of each of the first light emitting element ED_R and the third light emitting element ED_B, and the second power LV may be applied to the second ends. Accordingly, the first light emitting element ED_R and the third light emitting element ED_B may emit light.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments.

What is claimed is:

1. A display device comprising:
a bank layer disposed on a substrate and defining an emission area;
a first alignment electrode, a second alignment electrode, a third alignment electrode, a fourth alignment electrode, a fifth alignment electrode, and a sixth alignment electrode, each disposed on the substrate extending across the emission area, spaced apart from each other, and sequentially arranged in a direction;
a first light emitting element disposed between the first alignment electrode and the second alignment electrode in the emission area and emitting first light;
a second light emitting element disposed between the third alignment electrode and the fourth alignment electrode in the emission area and emitting second light; and
a third light emitting element disposed between the fifth alignment electrode and the sixth alignment electrode in the emission area and emitting third light;
wherein wavelengths of the first light, the second light, and the third light are different from each other.

2. The display device of claim 1, wherein a length of the first light emitting element, a length of the second light emitting element, and a length of the third light emitting element in the direction are different from each other.

3. The display device of claim 2, wherein
the first light has a peak wavelength in a range of about 610 nm to about 650 nm,
the second light has a peak wavelength in a range of about 510 nm to about 550 nm, and
the third light has a peak wavelength in a range of about 440 nm to about 480 nm.

4. The display device of claim 3, wherein
the length of the first light emitting element is greater than the length of the second light emitting element, and
the length of the second light emitting element is greater than the length of the third light emitting element.

5. The display device of claim 4, further comprising:
an anchor portion disposed on the first light emitting element, the second light emitting element, and the third light emitting element and exposing both ends of each of the first light emitting element, the second light emitting element, and the third light emitting element,
wherein the anchor portion comprises an organic insulating material.

6. The display device of claim 4, wherein
a distance between the first alignment electrode and the second alignment electrode is greater than a distance between the third alignment electrode and the fourth alignment electrode in the direction, and
the distance between the third alignment electrode and the fourth alignment electrode is greater than a distance between the fifth alignment electrode and the sixth alignment electrode in the direction.

7. The display device of claim 6, wherein
the length of the first light emitting element is greater than the distance between the first alignment electrode and the second alignment electrode,
the length of the second light emitting element is greater than the distance between the third alignment electrode and the fourth alignment electrode, and
the length of the third light emitting element is greater than the distance between the fifth alignment electrode and the sixth alignment electrode.

8. The display device of claim 1, further comprising:
a via insulating layer disposed between the substrate and each of the first alignment electrode, the second alignment electrode, the third alignment electrode, the fourth alignment electrode, the fifth alignment electrode, and the sixth alignment electrode,
wherein the each of the first alignment electrode, the second alignment electrode, the third alignment electrode, the fourth alignment electrode, the fifth alignment electrode, and the sixth alignment electrode has a flat profile in the emission area.

9. The display device of claim 8, wherein a bottom surface of the each of the first alignment electrode, the second alignment electrode, the third alignment electrode, the fourth alignment electrode, the fifth alignment electrode, and the sixth alignment electrode completely contacts a top surface of the via insulating layer in the emission area.

10. A display device comprising:
a bank layer disposed on a substrate and defining an emission area;
a first alignment electrode, a second alignment electrode, a third alignment electrode, and a fourth alignment electrode, each disposed on the substrate extending across the emission area, spaced apart from each other, and sequentially arranged in a direction;
a first light emitting element disposed between the first alignment electrode and the second alignment electrode in the emission area and emitting first light;
a second light emitting element disposed between the second alignment electrode and the third alignment electrode in the emission area and emitting second light; and
a third light emitting element disposed between the third alignment electrode and the fourth alignment electrode in the emission area and emitting third light;
wherein wavelengths of the first light, the second light, and the third light are different from each other.

11. The display device of claim 10, wherein a length of the first light emitting element, a length of the second light emitting element, and a length of the third light emitting element in the direction are different from each other.

12. The display device of claim 11, wherein
the first light has a peak wavelength in a range of about 610 nm to about 650 nm,
the second light has a peak wavelength in a range of about 510 nm to about 550 nm, and
the third light has a peak wavelength in a range of about 440 nm to about 480 nm.

13. The display device of claim 12, wherein
the length of the first light emitting element is greater than the length of the second light emitting element and
the length of the second light emitting element is greater than the length of the third light emitting element.

14. The display device of claim 13, wherein
a distance between the first alignment electrode and the second alignment electrode is greater than a distance between the second alignment electrode and the third alignment electrode in the direction, and
the distance between the second alignment electrode and the third alignment electrode is greater than a distance between the third alignment electrode and the fourth alignment electrode in the direction.

15. The display device of claim 10, wherein
each of the first light emitting element, the second light emitting element, and the third light emitting element have a first end and a second end having different polarities,
the second end of the first light emitting element faces the first end of the second light emitting element, and
the second end of the second light emitting element faces the first end of the third light emitting element.

16. The display device of claim 15, further comprising:
a first connection electrode disposed on the first alignment electrode,
a second connection electrode disposed on the second alignment electrode,
a third connection electrode disposed on the third alignment electrode, and
a fourth connection electrode disposed on the fourth alignment electrode, wherein
the first connection electrode electrically contacts the first end of the first light emitting element,
the second connection electrode electrically contacts the second end of the first light emitting element and the first end of the second light emitting element,
the third connection electrode electrically contacts the second end of the second light emitting element and the first end of the third light emitting element, and
the fourth connection electrode electrically contacts the second end of the third light emitting element.

17. The display device of claim 16, wherein each of the first connection electrode, the second connection electrode, the third connection electrode, and the fourth connection electrode receives a first voltage and a second voltage having different potential values.

18. The display device of claim 17, further comprising:
an anchor portion disposed on the first light emitting element, the second light emitting element, and the third light emitting element and exposing the first end and the second end of each of the first light emitting element, the second light emitting element, and the third light emitting element,
wherein the anchor portion comprises an organic insulating material.

19. The display device of claim 10, further comprising:
a via insulating layer disposed between the substrate and each of the first alignment electrode, the second alignment electrode, the third alignment electrode, and the fourth alignment electrode,
wherein the each of the first alignment electrode, the second alignment electrode, the third alignment electrode, and the fourth alignment electrode has a flat profile in the emission area.

20. The display device of claim 19, wherein a bottom surface of the each of the first alignment electrode, the second alignment electrode, the third alignment electrode, and the fourth alignment electrode completely contacts a top surface of the via insulating layer in the emission area.
